(19) United States
(12) Patent Application Publication
(10) Pub. No.: US 2026/0371552 A1
(43) Pub. Date: Nov. 19, 2026

(54) MEMORY DEVICES AND METHODS AND APPARATUS FOR MANUFACTURING THE SAME

(71) Applicant: Applied Materials, Inc., Santa Clara, CA (US)

(72) Inventors: Chang Seok Kang, Santa Clara, CA (US); Hoi Sung Chung, Sunnyvale, CA (US); Tomohiko Kitajima, San Jose, CA (US); Jongbeom Seo, San Jose, CA (US); Raghuveer Satya Makala, Campbell, CA (US); Balasubramanian Pranatharthiharan, San Jose, CA (US)

(73) Assignee: Applied Materials, Inc., Santa Clara, CA (US)

(21) Appl. No.: 19/206,345

(22) Filed: May 13, 2025

(51) Int. Cl. H10B 12/00

(52) U.S. Cl. CPC H10B 12/05; H10B 12/30

(57) ABSTRACT

Memory devices and methods and apparatus for manufacturing memory devices are described. The memory device comprises an array region including at least two unit cells stacked vertically on a substrate, the array region including a plurality of word lines; and a word line pad region including a plurality of word lines, wherein each of the plurality of word lines of the array region is connected to each of the plurality of word lines of the word line pad region in a first direction and a second direction.

### TECHNICAL FIELD

Embodiments of the present disclosure pertain to the field of electronic devices and methods and apparatus for manufacturing electronic devices. More particularly, embodiments of the disclosure provide memory devices and methods and apparatus for manufacturing memory devices.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values, but require periodic reprogramming or “refreshing” to maintain this voltage for more than very short periods of time. Static random-access memories (SRAMs) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and contacts to the bitline and to the wordline. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive word lines through the cell, the size of the cell capacitor, and the compatibility of array devices with nonarray devices.

Memory devices typically include an array region including at least two unit cells stacked vertically on a substrate and a word line pad region. Each of the array region and the word line pad region independently including a plurality of word lines. In current approaches, the respective word lines of the array region and the word line pad region are fabricated together, such that the word lines of the array region and the word lines of the word line pad region are already connected to each other. That is, in current approaches, there is a single word line replacement process. It has been found that in using these current approaches, there is non-occupied area in the word line pad region and there is increased word line resistance in the word line pad region.

Additionally, in current approaches where the word lines of the array region and the word line pad regions are fabricated together, the array region and the word line pad region each independently include the same film stack components. In current approaches where the word lines of the array region and the word line pad regions are fabricated together, the film stack of word line pad region includes an insulator layer, a conductive layer, a silicon channel and a gate oxide layer. However, the silicon channel and gate oxide layer are not necessary layers for the word line pad region. Thus, the volumes of the conductive layer and the insulator layer are smaller than in cases where the silicon channel and the gate oxide layer are not present in the word line pad region. The reduced volumes of the conductive layer and the insulator layer, respectively leads to a longer resistive-capacitive (RC) delay of the device.

Therefore, there is a need in the art for memory devices and methods of manufacturing memory devices that utilize non-occupied area in the word line pad region and/or have lower word line resistance in the word line pad region.

### SUMMARY

One or more embodiments of the disclosure are directed to a method of manufacturing a memory device. The method comprises selectively removing a plurality of first material layers from a film stack in an array region on a substrate. The array region includes at least two unit cells stacked vertically on the substrate. Each of the at least two unit cells includes a capacitor connected to a transistor. The transistor comprises a silicon channel and the film stack. The film stack comprises alternating layers of the plurality of first material layers, a plurality of second material layers, and a gate oxide material on the silicon channel. The method comprises removing a portion of the gate oxide material to form a plurality of word line cavities between each of the plurality of second material layers; and depositing a conductive material in each of the plurality of word line cavities to form a plurality of word line contacts. The plurality of word line contacts are configured to connect the array region with a word line pad region of the memory device in a first direction and a second direction.

Further embodiments of the disclosure are directed to a processing system. The processing system comprises a central transfer station comprising at least one robot configured to move a wafer; a plurality of processing stations, each processing station connected to the central transfer station and providing a processing region separated from processing regions of adjacent processing stations; and a controller connected to the central transfer station and the plurality of processing stations. The controller is configured to activate the robot to move the wafer between processing stations, including selectively removing a plurality of first material layers from a film stack in an array region on the wafer. The array region includes at least two unit cells stacked vertically on the wafer. Each of the at least two unit cells includes a capacitor connected to a transistor. The transistor comprises a silicon channel and the film stack. The film stack comprises alternating layers of the plurality of first material layers, a plurality of second material layers, and a gate oxide material on the silicon channel. The controller is configured to active the robot to remove a portion of the gate oxide material to form a plurality of word line cavities between each of the plurality of second material layers; and deposit a conductive material in each of the plurality of word line cavities to form a plurality of word line contacts. The plurality of word line contacts are configured to connect the array region with a word line pad region of the memory device in a first direction and a second direction.

Additional embodiments of the disclosure are directed to a memory device. The memory device comprises an array region including at least two unit cells stacked vertically on a substrate, the array region including a plurality of word lines; and a word line pad region including a plurality of word lines, wherein each of the plurality of word lines of the array region is connected to each of the plurality of word lines of the word line pad region in a first direction and a second direction.

### BRIEF DESCRIPTION OF THE DRAWINGS

So that the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope.

FIG. 1A illustrates a process flow diagram of a method according to one or more embodiments;

FIG. 1B illustrates a process flow diagram of a method according to one or more embodiments;

FIG. 1C illustrates a process flow diagram of a method according to one or more embodiments;

FIG. 2A illustrates a cross-sectional isometric view of semiconductor structure on a substrate according to one or more embodiments;

FIG. 2B illustrates an enlarged cross-sectional schematic view of the semiconductor structure of FIG. 2A;

FIG. 2C illustrates a cross-sectional isometric view of the semiconductor structure of FIG. 2A after etching;

FIG. 2D illustrates a cross-sectional isometric view of the semiconductor structure of FIG. 2C after etching and filling a portion of the semiconductor structure with a dielectric material;

FIG. 2E illustrates a cross-sectional isometric view of the semiconductor structure of FIG. 2D after etching;

FIG. 2F illustrates a cross-sectional isometric view of the semiconductor structure of FIG. 2E after etching;

FIG. 2G illustrates an enlarged cross-sectional schematic view of the semiconductor structure of FIG. 2F;

FIG. 2H illustrates a cross-sectional isometric view of the semiconductor structure of FIG. 2F after laterally filling a portion of the semiconductor structure with a dielectric material;

FIG. 2I illustrates a cross-sectional isometric view of the semiconductor structure of FIG. 2H after depositing a sacrificial layer;

FIG. 2J illustrates a cross-sectional isometric view of the semiconductor structure of FIG. 2I after etching;

FIG. 2K illustrates an enlarged cross-sectional schematic view of the semiconductor structure of FIG. 2J;

FIG. 2L illustrates a cross-sectional isometric view of the semiconductor structure of FIG. 2J after etching;

FIG. 2M illustrates an enlarged cross-sectional schematic view of the semiconductor structure of FIG. 2L;

FIG. 2N illustrates a cross-sectional isometric view of the semiconductor structure of FIG. 2L after etching;

FIG. 2O illustrates an enlarged cross-sectional schematic view of the semiconductor structure of FIG. 2N;

FIG. 2P illustrates a cross-sectional isometric view of the semiconductor structure of FIG. 2O after filling a portion of the semiconductor structure;

FIG. 2Q illustrates a cross-sectional isometric view of the semiconductor structure of FIG. 2P after filling a portion of the semiconductor structure;

FIG. 2R illustrates an enlarged cross-sectional schematic view of the semiconductor structure of FIG. 2Q;

FIG. 2S illustrates a cross-sectional isometric view of the semiconductor structure of FIG. 2R after a pull-back process;

FIG. 2T illustrates an enlarged cross-sectional schematic view of the semiconductor structure of FIG. 2S;

FIG. 2U illustrates a cross-sectional isometric view of the semiconductor structure of FIG. 2S after a gate formation process;

FIG. 2V illustrates an enlarged cross-sectional schematic view of the semiconductor structure of FIG. 2U;

FIG. 2W illustrates a cross-sectional isometric view of the semiconductor structure of FIG. 2V after etching;

FIG. 2X illustrates an enlarged cross-sectional schematic view of the semiconductor structure of FIG. 2W;

FIG. 2Y illustrates a cross-sectional isometric view of the semiconductor structure of FIG. 2X after a doping process;

FIG. 2Z illustrates an enlarged cross-sectional schematic view of the semiconductor structure of FIG. 2Y;

FIG. 3A illustrates a cross-sectional isometric view of the semiconductor structure of FIG. 2Y after a bit line formation process;

FIG. 3B illustrates an enlarged cross-sectional schematic view of the semiconductor structure of FIG. 3A;

FIG. 3C illustrates a cross-sectional isometric view of the semiconductor structure of FIG. 3A after etching;

FIG. 3D illustrates an enlarged cross-sectional schematic view of the semiconductor structure of FIG. 3C;

FIG. 3E illustrates a cross-sectional isometric view of the semiconductor structure of FIG. 3C after etching;

FIG. 3F illustrates an enlarged cross-sectional schematic view of the semiconductor structure of FIG. 3E;

FIG. 3G illustrates a cross-sectional isometric view of the semiconductor structure of FIG. 3E after depositing a sacrificial layer;

FIG. 3H illustrates an enlarged cross-sectional schematic view of the semiconductor structure of FIG. 3G;

FIG. 3I illustrates a cross-sectional isometric view of the semiconductor structure of FIG. 3G after etching;

FIG. 3J illustrates an enlarged cross-sectional schematic view of the semiconductor structure of FIG. 3I;

FIG. 3K illustrates a cross-sectional isometric view of the semiconductor structure of FIG. 3I after a doping process;

FIG. 3L illustrates an enlarged cross-sectional schematic view of the semiconductor structure of FIG. 3J;

FIG. 3M illustrates a cross-sectional isometric view of the semiconductor structure of FIG. 3K after depositing a bottom electrode;

FIG. 3N illustrates an enlarged cross-sectional schematic view of the semiconductor structure of FIG. 3M;

FIG. 3O illustrates a cross-sectional isometric view of the semiconductor structure of FIG. 3M after depositing a sacrificial layer;

FIG. 3P illustrates an enlarged cross-sectional schematic view of the semiconductor structure of FIG. 3O;

FIG. 3Q illustrates a cross-sectional isometric view of the semiconductor structure of FIG. 3O after etching;

FIG. 3R illustrates an enlarged cross-sectional schematic view of the semiconductor structure of FIG. 3Q;

FIG. 3S illustrates a cross-sectional isometric view of the semiconductor structure of FIG. 3Q after etching;

FIG. 3T illustrates an enlarged cross-sectional schematic view of the semiconductor structure of FIG. 3S;

FIG. 3U illustrates a cross-sectional isometric view of the semiconductor structure of FIG. 3S after a deposition process;

FIG. 3V illustrates an enlarged cross-sectional schematic view of the semiconductor structure of FIG. 3U;

FIG. 4A illustrates a cross-sectional isometric view of the semiconductor structure of FIG. 3U after etching;

FIG. 4B illustrates a cross-sectional isometric view of the semiconductor structure of FIG. 4A after etching;

FIG. 4C illustrates an enlarged cross-sectional schematic view of the semiconductor structure of FIG. 4B;

FIG. 4D illustrates a cross-sectional isometric view of the semiconductor structure of FIG. 4B after etching;

FIG. 4E illustrates an enlarged cross-sectional schematic view of the semiconductor structure of FIG. 4D;

FIG. 4F illustrates a cross-sectional isometric view of the semiconductor structure of FIG. 4D after laterally filling a portion of the semiconductor structure with a dielectric material;

FIG. 4G illustrates an enlarged cross-sectional schematic view of the semiconductor structure of FIG. 4F;

FIG. 4H illustrates a cross-sectional isometric view of the semiconductor structure of FIG. 4F after etching;

FIG. 4I illustrates an enlarged cross-sectional schematic view of the semiconductor structure of FIG. 4H;

FIG. 4J illustrates a cross-sectional isometric view of the semiconductor structure of FIG. 4H after etching;

FIG. 4K illustrates an enlarged cross-sectional schematic view of the semiconductor structure of FIG. 4J;

FIG. 4L illustrates a cross-sectional isometric view of the semiconductor structure of FIG. 4J after filling a portion of the semiconductor structure with a metallic material;

FIG. 4M illustrates an enlarged cross-sectional schematic view of the semiconductor structure of FIG. 4L;

FIG. 4N illustrates a cross-sectional isometric view of the semiconductor structure of FIG. 4L after filling a portion of the semiconductor structure with a dielectric material;

FIG. 4O illustrates a cross-sectional isometric view of the semiconductor structure of FIG. 4N after etching;

FIG. 4P illustrates an enlarged cross-sectional schematic view of the semiconductor structure of FIG. 4O;

FIG. 4Q illustrates a cross-sectional isometric view of the semiconductor structure of FIG. 4O after a deposition process;

FIG. 4R illustrates an enlarged cross-sectional schematic view of a portion of a memory device in accordance with one or more embodiments;

FIG. 4S illustrates a top schematic view of a portion of the memory device of FIG. 4R according to one or more embodiments;

FIG. 4T illustrates a cross-sectional schematic view of a portion of the memory device of FIG. 4S taken along line A-A′ and line Z-Z′; and

FIG. 4U illustrates an enlarged cross-sectional schematic view of a portion of the memory device of FIG. 4T.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the structure (e.g., substrate) in use or operation in addition to the orientation depicted in the Figures. For example, if the substrate in the Figures is turned over, elements described as “below” or “beneath” other elements would then be oriented “above” the other elements. Thus, the exemplary term “below” may encompass both an orientation of above and below. The substrate may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing an inert gas over the substrate. In one or more embodiments, the inert gas is selected from one or more of nitrogen (N₂), helium (He), and argon (Ar). In some embodiments, the first reactive species is purged from the reaction chamber for a time duration in a range of from 0.1 seconds to 30 seconds, for example, before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring of this description. Those of ordinary skill in the art, with the included description, will be able to implement appropriate functionality without undue experimentation.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In the buried word line (bWL), a word line is buried below the surface of a semiconductor substrate using a metal as a gate electrode.

Memory devices typically include an array region including at least two unit cells stacked vertically on a substrate and a word line pad region. Each of the array region and the word line pad region independently including a plurality of word lines. In current approaches, the respective word lines of the array region and the word line pad region are fabricated together, such that the word lines of the array region and the word lines of the word line pad region are already connected to each other. That is, in current approaches, there is a single word line replacement process. It has been found that in using these current approaches, there is non-occupied area in the word line pad region and there is increased word line resistance in the word line pad region.

Additionally, in current approaches where the word lines of the array region and the word line pad regions are fabricated together, the array region and the word line pad region each independently include the same film stack components. In current approaches where the word lines of the array region and the word line pad regions are fabricated together, the film stack of word line pad region includes an insulator layer, a conductive layer, a silicon channel and a gate oxide layer. However, the silicon channel and gate oxide layer are not necessary layers for the word line pad region. Thus, the volumes of the conductive layer and the insulator layer are smaller than in cases where the silicon channel and the gate oxide layer are not present in the word line pad region. The reduced volumes of the conductive layer and the insulator layer, respectively leads to a longer resistive-capacitive (RC) delay of the device.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Although the disclosure will routinely identify specific 3D-DRAM devices, and components thereof, it will be readily understood that the device and methods are equally applicable to other memory devices, including but not limited to NAND and/or 3D-NAND devices, orientations thereof, as processes for manufacturing such devices. Accordingly, the technology should not be considered to be so limited as for use with these specific devices or methods alone.

The processes described herein may be integrated and performed in any suitable processing system. In one or more embodiments, the processes described herein are performed in situ in an integrated processing system. The processing system may include any suitable processing chambers for fabricating a semiconductor device.

Embodiments of the disclosure are directed to memory devices, methods of manufacturing memory devices, and apparatus I.e., processing systems, for manufacturing memory devices.

Some embodiments advantageously provide memory devices (and methods of manufacturing memory devices and processing systems for manufacturing memory devices) having increased word line area in the word line pad region compared to current approaches. Some embodiments provide memory devices (and methods of manufacturing memory devices and processing systems for manufacturing memory devices) in which there are two word line replacement processes: one word line replacement process in the array region and another word line replacement process in the word line pad region.

Some embodiments advantageously provide memory devices (and methods of manufacturing memory devices and processing systems for manufacturing memory devices) having word line contact pad locations on the transistor side and the capacitor side compared to current approaches where only the transistor side word line contact pad location is available.

Some embodiments advantageously provide memory devices (and methods of manufacturing memory devices and processing systems for manufacturing memory devices) having reduced word line resistance in the word line pad region compared to current approaches. In one or more embodiments, the memory devices described herein advantageously have a word line resistance in the word line pad region that is reduced by up to 50% compared to memory devices formed by current approaches (e.g., a reduction in sheet resistance of 100 Ω/square to 50 Ω/square).

Some embodiments advantageously provide memory devices (and methods of manufacturing memory devices and processing systems for manufacturing memory devices) having increased word line thickness and insulator thickness compared to current approaches. Advantageously, it has been found that the memory devices having increased word line thickness and insulator thickness compared to current approaches described herein exhibit resistive-capacitive (RC) delay reduction. In one or more embodiments, the disclosed memory devices have a word line thickness of about 60 nm in a single gate in the word line pad region and have an insulator thickness of about 20 nm in the word line pad region.

In one or more embodiments, the disclosed methods of manufacturing memory devices and processing systems for manufacturing memory devices are configured to provide carbon fill, dielectric etch, e.g., oxide hard mask open, atomic layer deposition (ALD) of word line metallic material (e.g., molybdenum (Mo)), word line node separation, and selective silicon removal.

One or more embodiments of the disclosure are directed to a method of manufacturing a memory device. The method comprises selectively removing a plurality of first material layers from a film stack in an array region on a substrate. The array region includes at least two unit cells stacked vertically on the substrate. Each of the at least two unit cells includes a capacitor connected to a transistor. The transistor comprises a silicon channel and the film stack. The film stack comprises alternating layers of the plurality of first material layers, a plurality of second material layers, and a gate oxide material on the silicon channel. The method comprises removing a portion of the gate oxide material to form a plurality of word line cavities between each of the plurality of second material layers; and depositing a conductive material in each of the plurality of word line cavities to form a plurality of word line contacts. The plurality of word line contacts are configured to connect the array region with a word line pad region of the memory device in a first direction and a second direction.

In specific embodiments, the method comprises: selectively removing a plurality of silicon layers from a film stack in an array region on a substrate, the array region including at least two unit cells stacked vertically on the substrate, each of the at least two unit cells including a capacitor connected to a transistor, the transistor comprising a silicon channel and the film stack, the film stack comprising alternating layers of the plurality of silicon layers, a plurality of silicon germanium layers, and a gate oxide material comprising silicon oxide on the silicon channel; removing a portion of the gate oxide material to form a plurality of word line cavities between each of the plurality of second material layers; and depositing a conductive material (one or more of doped silicon, molybdenum (Mo), tungsten (W), titanium nitride (TiN), or tantalum nitride (TaN)) in each of the plurality of word line cavities to form a plurality of word line contacts, wherein the plurality of word line contacts are configured to connect the array region with a word line pad region of the memory device in a first direction and a second direction. The plurality of word line contacts are configured to connect each of a plurality of word lines of the array region with each of a plurality of word lines of the word line pad region in a first direction (extending parallel in a z-direction relative to the substrate) and a second direction (extending vertically relative to the substrate).

Further embodiments of the disclosure are directed to a processing system. The processing system comprises a central transfer station comprising at least one robot configured to move a wafer; a plurality of processing stations, each processing station connected to the central transfer station and providing a processing region separated from processing regions of adjacent processing stations; and a controller connected to the central transfer station and the plurality of processing stations. The controller is configured to activate the robot to move the wafer between processing stations, including selectively removing a plurality of first material layers from a film stack in an array region on the wafer. The array region includes at least two unit cells stacked vertically on the wafer. Each of the at least two unit cells includes a capacitor connected to a transistor. The transistor comprises a silicon channel and the film stack. The film stack comprises alternating layers of the plurality of first material layers, a plurality of second material layers, and a gate oxide material on the silicon channel. The controller is configured to active the robot to remove a portion of the gate oxide material to form a plurality of word line cavities between each of the plurality of second material layers; and deposit a conductive material in each of the plurality of word line cavities to form a plurality of word line contacts. The plurality of word line contacts are configured to connect the array region with a word line pad region of the memory device in a first direction and a second direction.

Additional embodiments of the disclosure are directed to a memory device. The memory device comprises an array region including at least two unit cells stacked vertically on a substrate, the array region including a plurality of word lines; and a word line pad region including a plurality of word lines, wherein each of the plurality of word lines of the array region is connected to each of the plurality of word lines of the word line pad region in a first direction and a second direction.

In one or more embodiments, each of the plurality of word lines of the array region independently comprise one or more of doped silicon, molybdenum (Mo), tungsten (W), titanium nitride (TiN), or tantalum nitride (TaN). In one or more embodiments, each of the plurality of word lines of the word line pad region independently comprise one or more of doped silicon, molybdenum (Mo), tungsten (W), titanium nitride (TiN), or tantalum nitride (TaN). In one or more embodiments, each of the plurality word lines of the array region and each of the plurality of word lines of the word line pad region independently comprise one or more of doped silicon, molybdenum (Mo), tungsten (W), titanium nitride (TiN), or tantalum nitride (TaN). In one or more embodiments, each of the plurality word lines of the array region comprise a different material than each of the plurality of word lines of the word line pad region.

The embodiments of the disclosure are described by way of the Figures, which illustrate process flow diagrams, semiconductor structures, and memory devices in accordance with one or more embodiments of the disclosure. The skilled artisan will recognize that the disclosed processes are not limited to the illustrated applications.

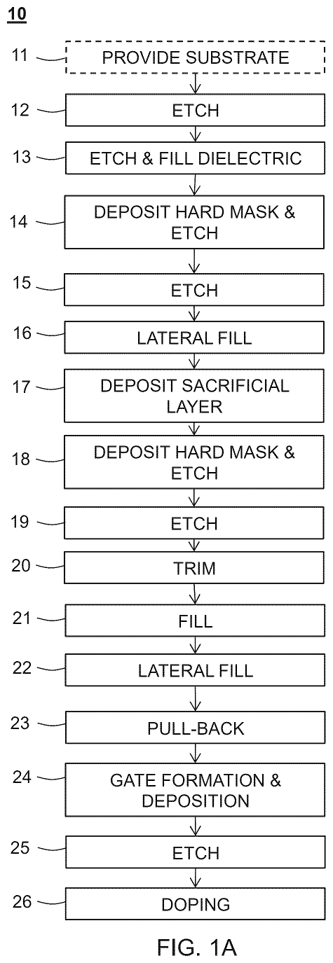

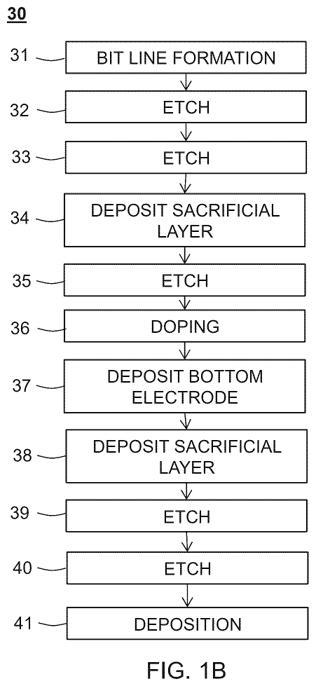

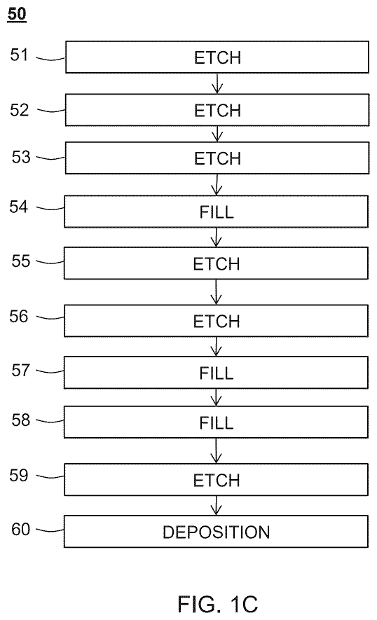

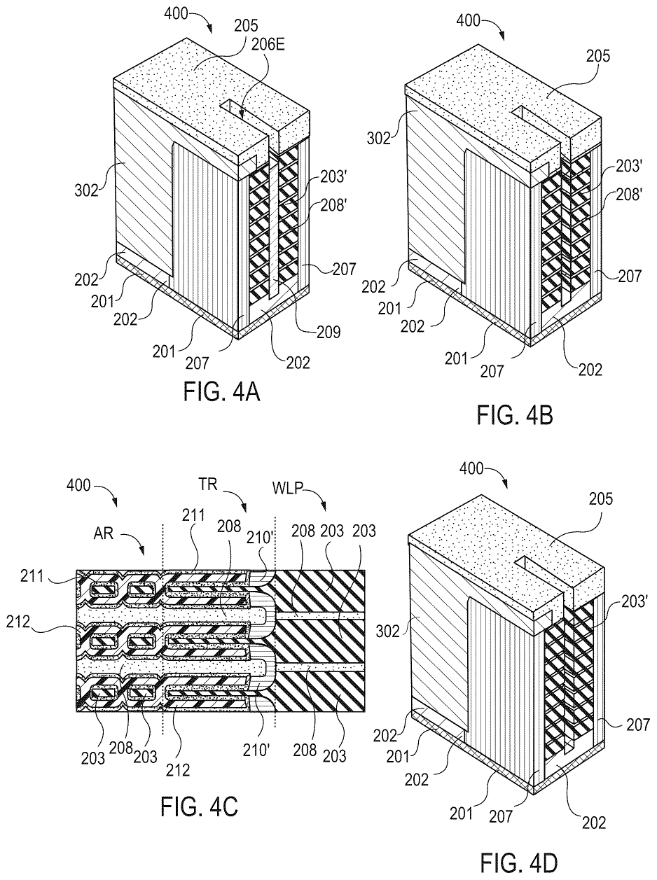

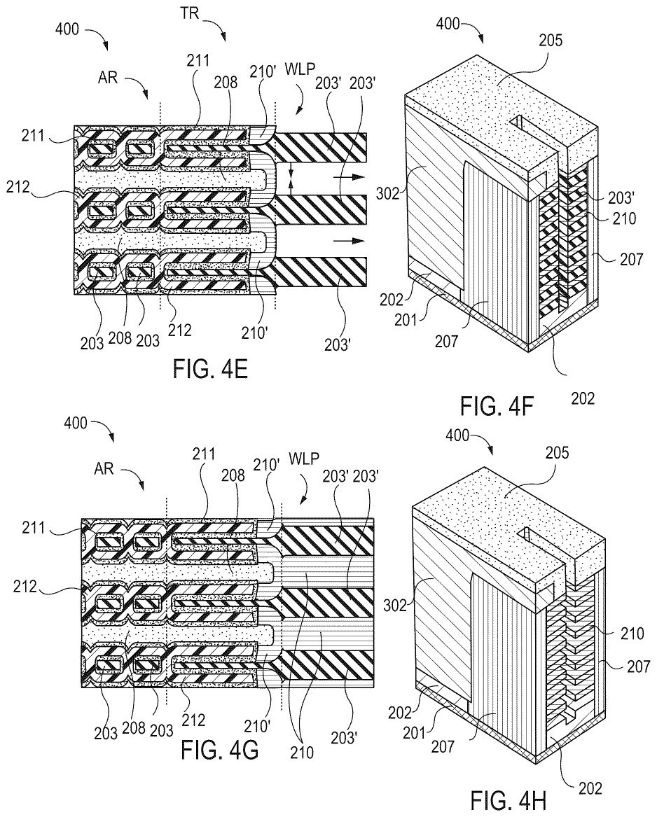

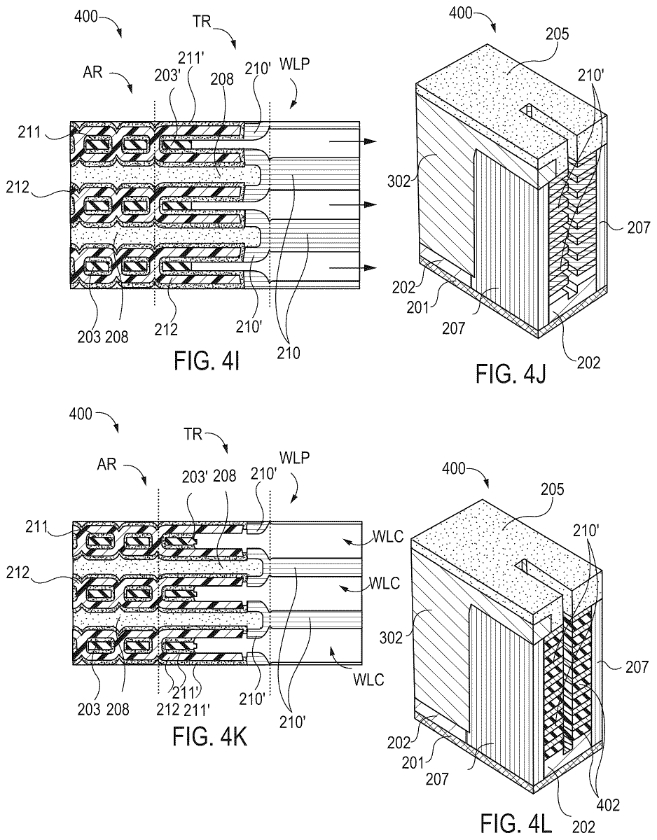

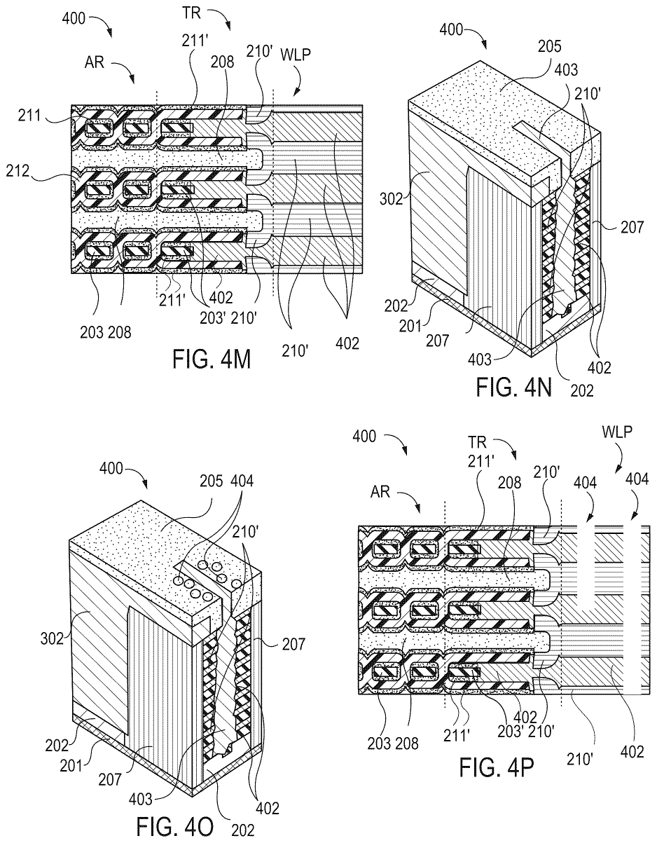

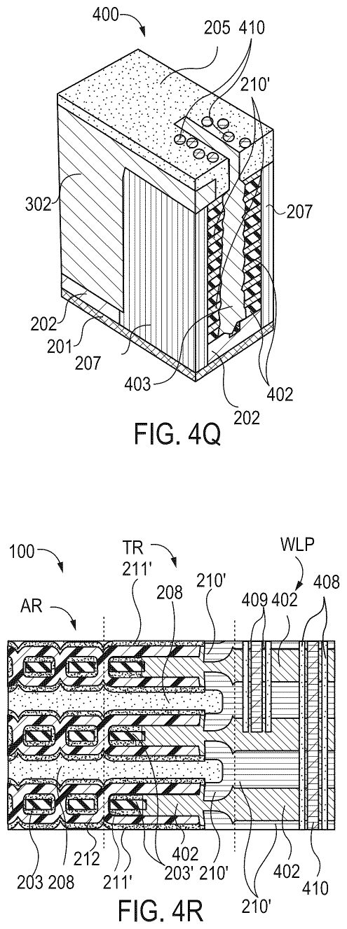

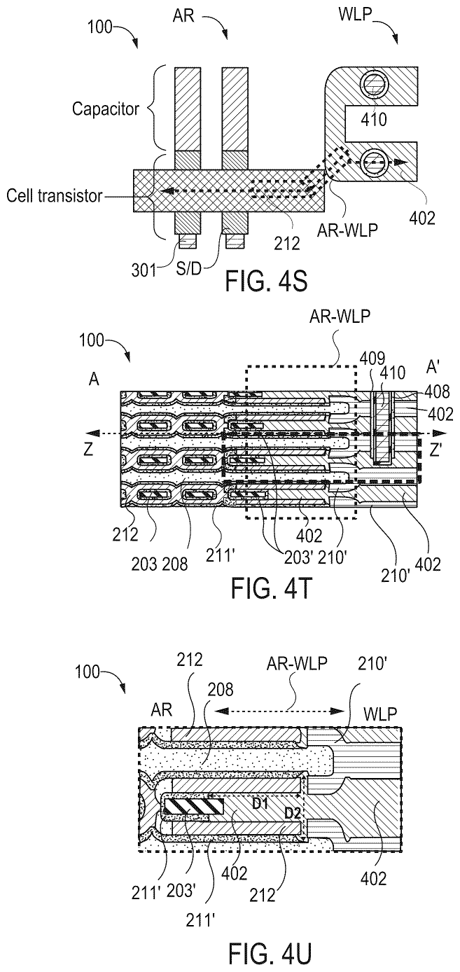

FIG. 1A illustrates a process flow diagram of a method 10. FIG. 1B illustrates a process flow diagram of a method 30. FIG. 1C illustrates a process flow diagram of a method 50. In one or more embodiments, the method 10, the method 30, and the method 50 collectively provide an integration scheme for manufacturing a memory device 100, shown in FIG. 4R-4U. In one or more embodiments, each of the method 10, the method 30, and the method 50 independently represent a portion of the integration scheme for manufacturing the memory device 100.

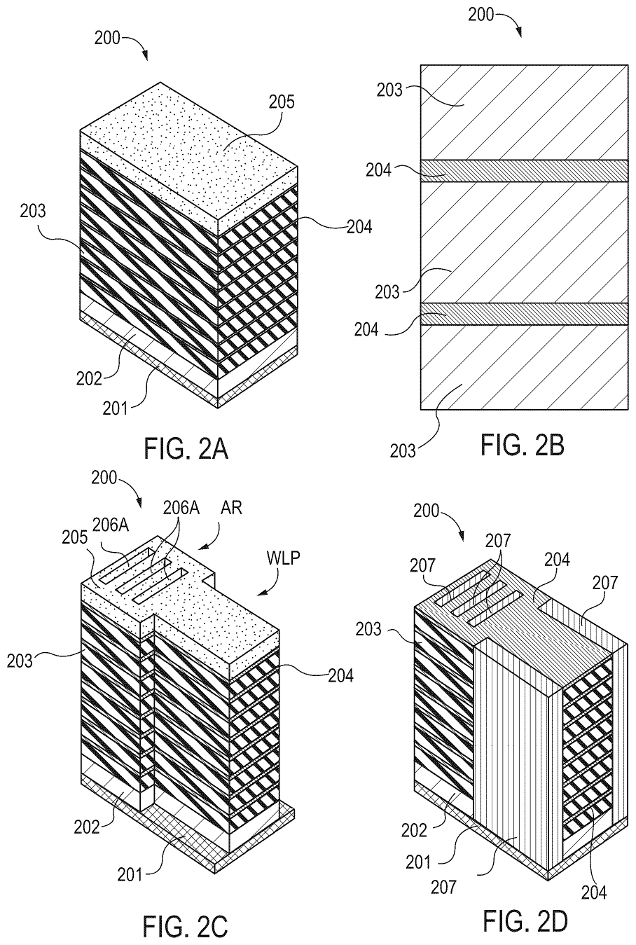

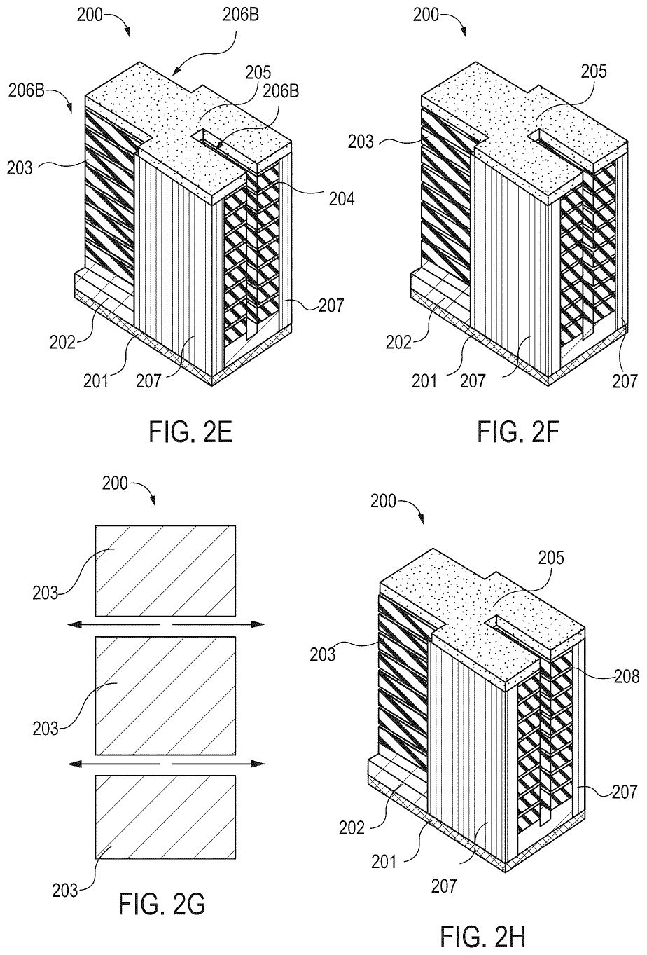

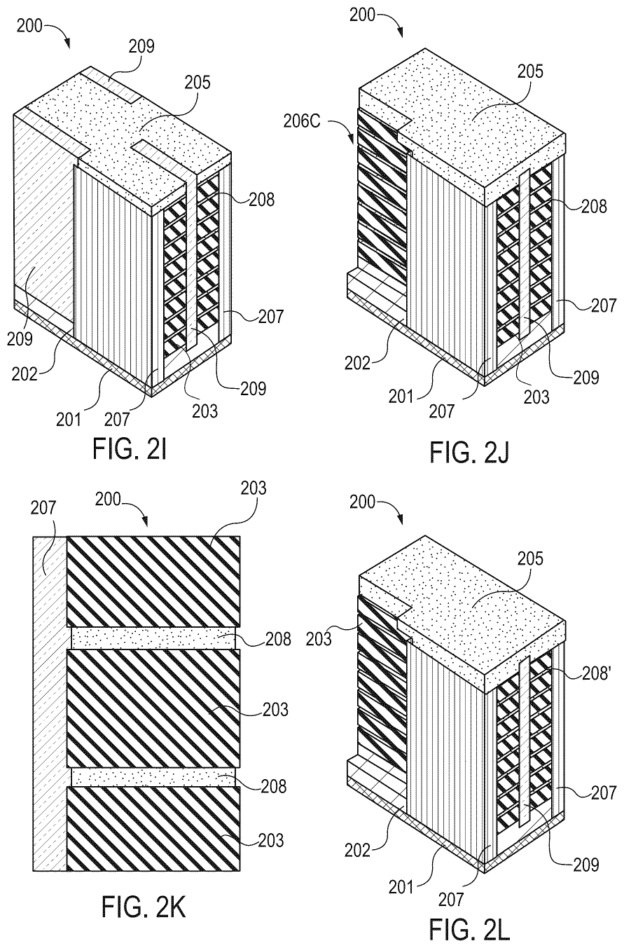

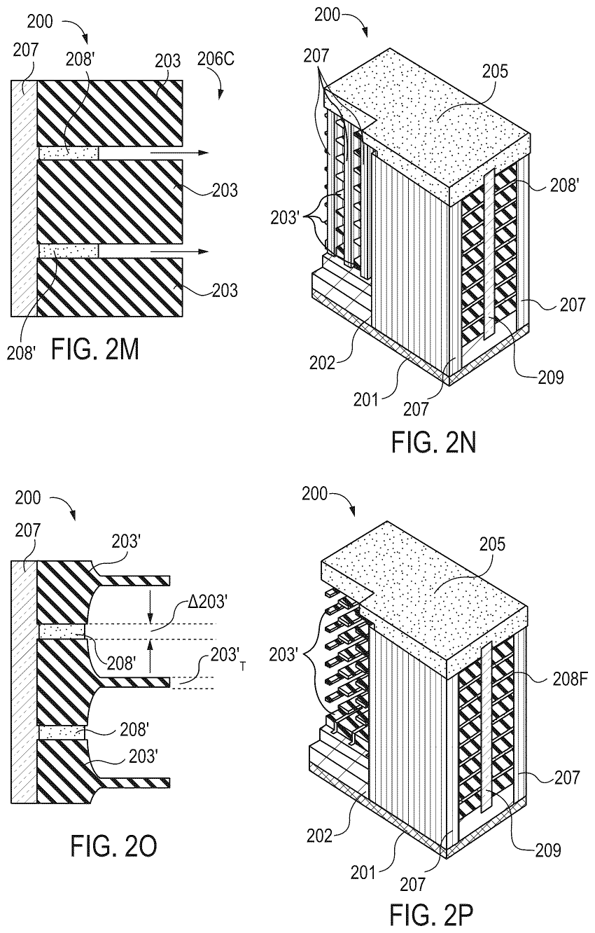

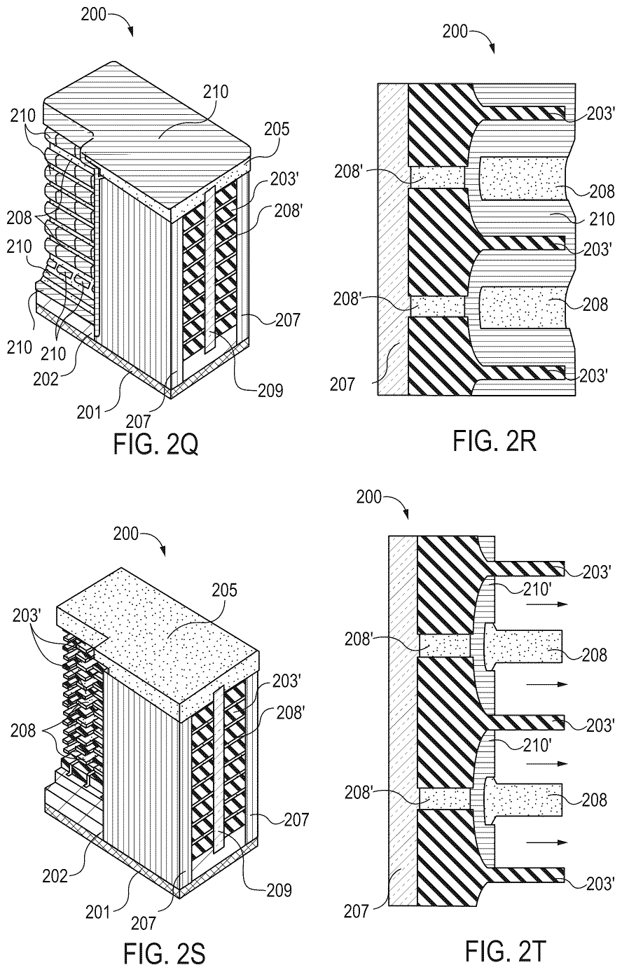

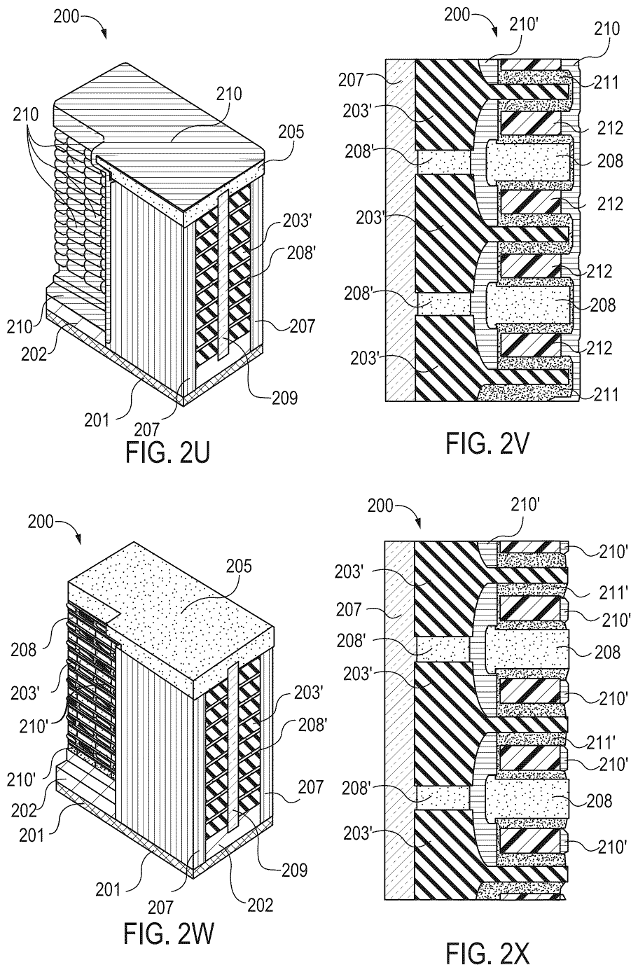

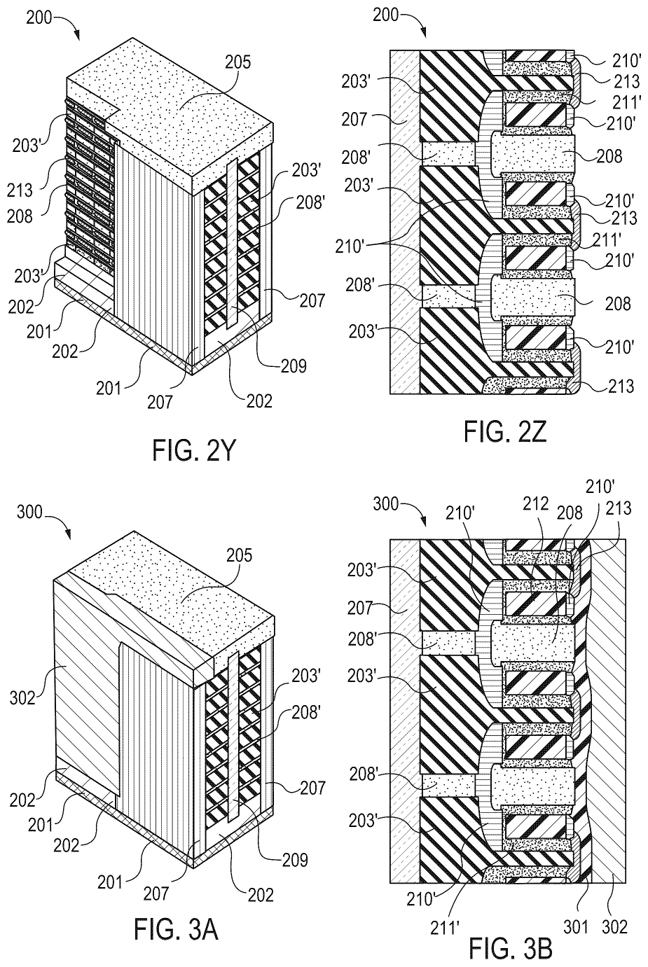

The method 10 is described with reference to FIG. 1A and FIG. 2A-2Z. In one or more embodiments, the method 10 is a method of processing a substrate 202 of a semiconductor structure 200 as part of the integration scheme for manufacturing the memory device 100.

The method 10 begins by optionally providing the substrate 202 at operation 11 (denoted by the box in dashed lines). In one or more embodiments, the substrate 202 is made available for processing. In one or more embodiments where the substrate 202 is made available for processing, operation 11 is not performed, and the substrate 202 is processed in accordance with the method 10 without “providing the substrate 202.”

FIG. 2A illustrates a cross-sectional isometric view of the semiconductor structure 200 on the substrate 202. In FIG. 2A, the substrate 202 is positioned on a substrate support surface 201. The substrate 202 can be to any substrate or material surface formed on a substrate upon which film processing is performed during a fabrication process. In some embodiments, the substrate 202 comprises one or more of doped or undoped crystalline silicon (Si), doped or undoped crystalline silicon germanium (SiGe), doped or undoped amorphous silicon (Si), or doped or undoped amorphous silicon germanium (SiGe).

Referring to FIGS. 2A and 2B, in one or more embodiments, the substrate 202 includes a plurality of alternating layers of a first material and a second material. FIG. 2B illustrates an enlarged cross-sectional schematic view of the semiconductor structure 200 of FIG. 2A. In one or more embodiments, the substrate 202 includes a film stack thereon, the film stack comprising a plurality of alternating layers of a first material and a second material (i.e., a plurality of first material layers and a plurality of second material layers). In one or more embodiments, each of the plurality of first material layers comprise silicon and each of the plurality of second material layers comprise silicon germanium or silicon oxide. In one or more embodiments, each of the plurality of first material layers comprise silicon and each of the plurality of second material layers comprise silicon germanium (i.e., a plurality of alternating layers of silicon and silicon germanium).

In one or more embodiments where the film stack includes a plurality of alternating layers of silicon and silicon germanium, the silicon layers or plurality of silicon layers are denoted by reference numeral “203” and the silicon germanium layers are denoted by reference numeral “204”. As used herein, the term “plurality of silicon layers 203” and “silicon layers 203” can be used interchangeably unless the context clearly indicates otherwise. As used herein, the term “plurality of silicon germanium layers 204” and “silicon germanium layers 204” can be used interchangeably unless the context clearly indicates otherwise.

In one or more embodiments, each of the plurality of silicon layers 203 are deposited by an epitaxial deposition process. In one or more embodiments, each of the plurality of silicon germanium layers 204 are deposited by an epitaxial deposition process. In one or more embodiments, each of the plurality of silicon germanium layers 204 independently have a germanium concentration in a range of from 1 at. % to 50 at. % germanium.

Each of the plurality of silicon layers 203 may independently have any suitable thickness. In one or more embodiments, each of the plurality of silicon layers 203 independently have a thickness in a range of from 10 nm to 70 nm. In one or more embodiments, the plurality of silicon layers 203 defines a silicon channel.

Each of the plurality of silicon germanium layers 204 may independently have any suitable thickness. In one or more embodiments, each of the plurality of silicon germanium layers 204 independently have a thickness in a range of from 10 nm to 70 nm.

In one or more embodiments, the substrate 102 includes a hard mask 205 formed on a top surface of the plurality of alternating layers of silicon and silicon germanium. The hard mask 205 can include any suitable material. In one or more embodiments, the hard mask 205 includes a carbon-containing material.

FIG. 2C illustrates a cross-sectional isometric view of the semiconductor structure 200 of FIG. 2A after etching, in accordance with operation 12, to form a first trench 206A.

The semiconductor structure 200 includes an array region AR and a word line pad region WLP. As will be described in greater detail herein, the array region AR includes at least two unit cells stacked vertically on the substrate 202. In one or more embodiments, the first trench 206A includes at least one trench. In one or more embodiments, the first trench 206A includes at least one trench in the array region AR and at least one trench in the word line pad region WLP. In one or more embodiments, the first trench 206A includes at least one trench extending through the hard mask 205 and the plurality of alternating layers of silicon and silicon germanium down to a top surface of the substrate 202.

The first trench 206A can have any suitable dimensions. In one or more embodiments, the first trench 206A has a critical dimension (CD) in a range of from 30 nm to 100 nm. In one or more embodiments, the first trench 206A has a length in a range of from 50 nm to 1000 nm.

FIG. 2D illustrates a cross-sectional isometric view of the semiconductor structure 200 of FIG. 2C after etching to remove the hard mask 205 and filling a portion of the semiconductor structure 200 with a dielectric material 207, in accordance with operation 13. In one or more embodiments, etching to remove the hard mask 205 exposes one of the silicon germanium layers 204. In FIG. 2D, the dielectric material 207 is shown as filling the first trench 206A extending through the plurality of alternating layers of silicon and silicon germanium down to the top surface of the substrate 202 and the at least one trench in the array region AR and the at least one trench in the word line pad region WLP.

The dielectric material 207 can be deposited by any suitable deposition technique. In one or more embodiments, the dielectric material 207 is a low-κ dielectric material. In one or more embodiments, the dielectric material 207 comprises doped or undoped silicon oxide. In one or more embodiments, the dielectric material 207 comprises doped silicon oxide, doped with one or more of carbon or nitrogen. In one or more embodiments, the dielectric material 207 comprises doped silicon oxide, doped with carbon and nitrogen, and having a formula of SiOCₓN_{y}, where x is in a range of from 1 at. % to 30 at. % carbon and y is in a range of from 1 at. % to 30 at. % nitrogen.

FIG. 2E illustrates a cross-sectional isometric view of the semiconductor structure 200 of FIG. 2D after depositing the hard mask 205 on the top surface of the plurality of alternating layers of silicon and silicon germanium and etching to form a second trench 206B, in accordance with operation 14.

In one or more embodiments, the second trench 206B includes at least one trench. In one or more embodiments, the second trench 206B includes at least one trench in the array region AR and at least one trench in the word line pad region WLP. In one or more embodiments, the second trench 206B includes at least one trench extending through the hard mask 205 and the plurality of alternating layers of silicon and silicon germanium down to the top surface of the substrate 202.

The second trench 206B can have any suitable dimensions. In one or more embodiments, the second trench 206B has a critical dimension (CD) in a range of from 50 nm to 200 nm. In one or more embodiments, the second trench 206B has a length in a range of from 50 nm to 1000 nm. In one or more embodiments, the second trench 206B has different dimensions than the first trench 206A.

In one or more embodiments, the first trench 206A, i.e., the at least one trench in the array region AR and the at least one trench in the word line pad region WLP is orthogonal to the second trench 206B, the at least one trench in the array region AR and the at least one trench in the word line pad region WLP, respectively.

FIG. 2F illustrates a cross-sectional isometric view of the semiconductor structure 200 of FIG. 2E after etching to remove each of the plurality of silicon germanium layers 204, in accordance with operation 15. FIG. 2G illustrates an enlarged cross-sectional schematic view of the semiconductor structure 200 of FIG. 2F.

The etching process depicted by FIGS. 2F and 2G, at operation 15, removes each of the plurality of silicon germanium layers 204 without removing the plurality of silicon layers 203. In some embodiments, the etching process is a selective isotropic etching process (e.g., a selective dry etching process or a selective wet etching process), and the extent of which the plurality of silicon germanium layers 204 is removed is controlled by duration of the etching process. In some embodiments, the selective wet etching process may include a hydro fluoride (HF), fluoride (F₂) or NH4OH etchant. In the one or more embodiments, the selective removal of the plurality of silicon germanium layers 204 may include a SiGe oxidation process followed by a SiGeOx removal. For example, the SiGe oxidation process may include forming and patterning various masking layers such that the oxidation is controlled to the plurality of silicon germanium layers 204. In other embodiments, the SiGe oxidation process is a selective oxidation due to the different compositions of the silicon layers 203 and the silicon germanium layers 204, respectively. In some embodiments, the SiGe oxidation process may be performed by exposing the substrate 202 to a wet oxidation process, a dry oxidation process, or a combination thereof. Thereafter, in embodiments where the SiGe oxidation process is performed, each of the plurality of silicon germanium layers 204, are removed by an etchant such as NH₄OH or diluted HF.

The etching process depicted by FIGS. 2F and 2G removes each of the plurality of silicon germanium layers 204 without removing the plurality of silicon layers 203, thereby leaving a space between each of the plurality of silicon layers 203 (denoted by the arrows in FIG. 2G).

FIG. 2H illustrates a cross-sectional isometric view of the semiconductor structure 200 of FIG. 2F after laterally filling a portion of the semiconductor structure 200 with a dielectric material 208, in accordance with operation 16. In one or more embodiments, the dielectric material 208 is formed in the space between each of the plurality of silicon layers 203. In one or more embodiments, the plurality of silicon germanium layers 204, which were removed in FIGS. 2F and 2G, are replaced with the dielectric material 208 in FIG. 2H.

The dielectric material 208 can be deposited by any suitable deposition technique. In one or more embodiments, the dielectric material 208 is the same as dielectric material 207. In some embodiments, the dielectric material 208 comprises one or more of silicon oxide (SiOx), silicon nitride (SiN), or silicon oxynitride (SiON). In one or more embodiments, the dielectric material 208 comprises silicon oxide (SiOx) deposited by atomic layer deposition (ALD). In one or more embodiments, the dielectric material 208 comprises silicon oxide (SiOx) deposited by atomic layer deposition (ALD) and having a thickness in a range of from 5 nm to 30 nm. In one or more embodiments, the dielectric material 208, e.g., each of the dielectric layers 208 independently has a length in a range of from 50 nm to 200 nm.

FIG. 2I illustrates a cross-sectional isometric view of the semiconductor structure 200 of FIG. 2H after depositing a sacrificial layer 209 to fill the second trench 206B, in accordance with operation 17. In one or more embodiments, the sacrificial layer 209 fills the second trench 206B, e.g., the at least one trench in the array region AR and at least one trench in the word line pad region WLP, and the at least one trench extending through the hard mask 205 and the plurality of alternating layers of silicon and silicon germanium down to the top surface of the substrate 202.

The sacrificial layer 209 can be any suitable material. In one or more embodiments, the sacrificial layer 209 comprises carbon.

FIG. 2J illustrates a cross-sectional isometric view of the semiconductor structure of FIG. 2I after depositing the hard mask 205 on top of the sacrificial layer 209 and on top of the plurality of alternating layers of the silicon (i.e., the plurality of silicon layers 203) and dielectric (i.e., the dielectric material 208 which replaced the plurality of silicon germanium layers 204) and etching the substrate 202 to form a third trench 206C, in accordance with operation 18. FIG. 2K illustrates an enlarged cross-sectional schematic view of the semiconductor structure 200 of FIG. 2J.

The third trench 206C defines a cavity through a word line in the array region AR is formed. The third trench 206C can be formed by any suitable process, such as by one or more of the etching processes described herein. In one or more embodiments, the third trench 206C is formed by top hard mask 205 opening and subsequent ashing of the sacrificial layer 209 (e.g., carbon).

FIG. 2L illustrates a cross-sectional isometric view of the semiconductor structure 200 of FIG. 2J after etching, in accordance with operation 19. FIG. 2M illustrates an enlarged cross-sectional schematic view of the semiconductor structure 200 of FIG. 2L.

In one or more embodiments, in accordance with operation 19, FIGS. 2L and 2M illustrate etching the dielectric material 208 (i.e., dielectric layers 208) to form recessed dielectric layers 208′. In one or more embodiments, etching the dielectric material 208 (i.e., dielectric layers 208) comprises any suitable etching process, such as the etching processes described herein. Any suitable amount of the dielectric material 208 (i.e., dielectric layers 208) can be etched (i.e., a recessed amount) to form the recessed dielectric layers 208′. In one or more embodiments, the recessed amount is in a range of from 100 nm to 300 nm.

FIG. 2N illustrates a cross-sectional isometric view of the semiconductor structure 200 of FIG. 2L after etching. FIG. 2O illustrates an enlarged cross-sectional schematic view of the semiconductor structure 200 of FIG. 2N. In FIGS. 2N and 2O, in accordance with operation 20, each of the plurality of silicon layers 203 are etched to form recessed silicon layers 203′.

In one or more embodiments, etching each of the plurality of silicon layers 203 comprises any suitable etching process, such as the etching processes described herein. In one or more embodiments, the plurality of silicon layers 203 are trimmed (to form a trimmed amount Δ203′) by exposing the substrate 202 to tetramethylammonium hydroxide (TMAH).

In one or more embodiments, each of the plurality of silicon layers 203 independently have a thickness in a range of from 10 nm to 70 nm. In one or more embodiments, the trimmed amount Δ203′ is in a range of from 5 nm to 30 nm. In one or more embodiments, each of the recessed silicon layers 203′ have a thickness 203′_{T} in a range of from 10 nm to 65 nm, including in a range of from 10 nm to 60 nm, or 10 nm to 40 nm.

FIG. 2P illustrates a cross-sectional isometric view of the semiconductor structure 200 of FIG. 2O after filling a portion of the semiconductor structure 200, in accordance with operation 21. In one or more embodiments, in FIG. 2P, a dielectric material 208F is filled in the first trench 206A, e.g., the at least one trench extending through the hard mask 205 and the recessed silicon layers 203′ and recessed dielectric layers 208′ down to the top surface of the substrate 202. In one or more embodiments, the dielectric material 208 and the dielectric material 208F are the same. In one or more embodiments, the dielectric material 208F comprises silicon oxycarbonitride (SiOCN). In one or more embodiments, the dielectric material 208F has a thickness in a range of from 5 nm to 50 nm.

FIG. 2Q illustrates a cross-sectional isometric view of the semiconductor structure 200 of FIG. 2P after filling a portion of the semiconductor structure 200 in accordance with operation 22. FIG. 2R illustrates an enlarged cross-sectional schematic view of the semiconductor structure of FIG. 2Q. In FIGS. 2Q and 2R, in one or more embodiments, a dielectric material 210 is deposited on top of the hard mask 205 and in the third trench 206C. The dielectric material 210 can be any suitable dielectric material. In one or more embodiments, the dielectric material 210 is deposited directly on the recessed silicon layers 203′ and the recessed dielectric layers 208′. In one or more embodiments, the dielectric material 208 is deposited directly on the dielectric material 210 that is deposited directly on the recessed silicon layers 203′ and the recessed dielectric layers 208′. In one or more embodiments, the dielectric material 210 and the dielectric material 208 collectively fill the third trench 206C.

In FIGS. 2Q and 2R, in one or more embodiments, the dielectric material 208 comprises silicon oxide (SiOx) and the dielectric material 210 comprises silicon nitride (SiN). In one or more embodiments where the dielectric material 208 comprises silicon oxide (SiOx) and the dielectric material 210 comprises silicon nitride (SiN), the dielectric material 210 is deposited by atomic layer deposition (ALD) to a thickness in a range of from 15 nm to 30 nm directly on the recessed silicon layers 203′ and the recessed dielectric layers 208′, and the dielectric material 208 is deposited by atomic layer deposition (ALD) to a thickness in arrange of from 5 nm to 15 nm directly on the dielectric material 210.

FIG. 2S illustrates a cross-sectional isometric view of the semiconductor structure 200 of FIG. 2R after a pull-back process, in accordance with operation 23. FIG. 2T illustrates an enlarged cross-sectional schematic view of the semiconductor structure 200 of FIG. 2S. In FIGS. 2S and 2T, in one or more embodiments, the pull-back process comprises etching to remove a portion of the dielectric material 210 to form recessed dielectric layers 210′. In one or more embodiments, etching to remove the portion of the dielectric material 210 to form the recessed dielectric layers 210′ exposes the dielectric material 208.

The pull-back process can include any suitable etching process, such as one or more of the etching processes described herein. In one or more embodiments, the pull-back process includes exposing the substrate 202 to hot phosphoric acid (H₃PO₄) remove the portion of the dielectric material 210 to form the recessed dielectric layers 210′. Any suitable amount of the dielectric material 210 can be etched (i.e., a recessed amount) to form the recessed dielectric layers 210′. In one or more embodiments, the recessed amount is in a range of from 80 nm to 280 nm. The amount of the dielectric material 210 etched (i.e., the recessed amount) to form the recessed dielectric layers 210′ is denoted by the arrows in FIG. 2T pointed towards the third trench 206C.

FIG. 2U illustrates a cross-sectional isometric view of the semiconductor structure 200 of FIG. 2S after a gate formation process, in accordance with operation 24. FIG. 2V illustrates an enlarged cross-sectional schematic view of the semiconductor structure 200 of FIG. 2U. In FIGS. 2U and 2V, in one or more embodiments, the gate formation process comprises deposition of a gate oxide material 211 directly on the exposed dielectric material 208 and on the remaining portion of the recessed dielectric layers 210′. In one or more embodiments, the gate oxide material 211 is deposited directly on the recessed silicon layers 203′.

In one or more embodiments, the gate oxide material 211 surrounds each of the plurality of silicon layers 203, e.g., the silicon channel. The gate oxide material 211 can include any suitable dielectric material. In one or more embodiments, the gate oxide material 211 comprises silicon oxide (SiOx).

The gate oxide material 211 can have any suitable thickness. In one or more embodiments, the gate oxide material 211 has a thickness in a range of from 2 nm to 10 nm, such as, for example, 3 nm to 8 nm.

In FIGS. 2U and 2V, in one or more embodiments, the gate formation process further comprises deposition of a gate 212 directly on the gate oxide material 211. The gate 212 can include any suitable material. In one or more embodiments, the gate 212 comprises a metallic material. In one or more embodiments, the gate 212 comprises one or more of doped silicon, molybdenum (Mo), tungsten (W), titanium nitride (TiN), or tantalum nitride (TaN). In one or more embodiments, the gate 212 comprises titanium nitride (TiN). In one or more embodiments, the gate 212 comprises molybdenum (Mo). As will be described in greater detail below, the gate 212 defines a plurality of word lines in array region AR.

In accordance with operation 24, FIGS. 2U and 2V also illustrate deposition of the dielectric material 210 (e.g., silicon nitride) after the gate formation process. Prior to the deposition of the dielectric material 210, gate material of the gate 212 deposited on the sidewall of the word line cavity is removed to isolate word lines of each stack with adjacent word lines (e.g., word lines above and/or below one another), which is referred to as “gate node separation.” The gate material of the gate 212 on the sidewall can be removed any suitable etching process, such as, for example, an isotropic etching process. In one or more embodiments of the gate node separation, the gate material is etched by an amount that is about 110% of the thickness the gate 212 deposition. i.e., if about 20 nm of the gate 212 is deposited, about 22 nm of the gate 212 on the sidewall is etched. Due to the sidewall etching, each gate 212 is separated from adjacent vertical gate layers. In one or more embodiments, after the gate formation process, the dielectric material 210 is deposited on top of the hard mask 205 and in the third trench 206C. In one or more embodiments, the dielectric material 210 is directly on the gate 212. In one or more embodiments, the dielectric material 210 is directly on the gate oxide material 211. In one or more embodiments, the dielectric material 210 is directly on the gate oxide material 211 and the gate 212.

FIG. 2W illustrates a cross-sectional isometric view of the semiconductor structure 200 of FIG. 2V after etching, in accordance with operation 25. FIG. 2X illustrates an enlarged cross-sectional schematic view of the semiconductor structure 200 of FIG. 2W. In FIGS. 2W and 2X, in one or more embodiments, the substrate 202 is etched to remove the dielectric material 210 from the top of the hard mask 205 (to expose the hard mask 205) and from the third trench 206C to form recessed dielectric layers 210′. In one or more embodiments, the recessed dielectric layers 210′ in the third trench 206C cover the gate 212. In one or more embodiments, etching the substrate 202 to remove the dielectric material 210 and the third trench 206C to form the recessed dielectric layers 210′ removes a portion of the gate oxide material 211 (to form recessed gate oxide material 211′) and exposes the recessed silicon layers 203′.

FIG. 2Y illustrates a cross-sectional isometric view of the semiconductor structure 200 of FIG. 2X after a doping process, in accordance with operation 26. FIG. 2Z illustrates an enlarged cross-sectional schematic view of the semiconductor structure 200 of FIG. 2Y. In FIGS. 2Y and 2Z, in one or more embodiments, the doping process is an N+ doping process in which, in the third trench 206C, the recessed silicon layers 203′ that were exposed (in FIG. 2V) are doped with an n-type dopant. In one or more embodiments, the n-type dopant is phosphorous (P). In one or more embodiments, the recessed silicon layers 203′ that were exposed (in FIG. 2V) are exposed to gas phase phosphine (PH₃) as a doping gas at temperature in a range of from 500 °C to 900 °C.

In one or more embodiments, the N+ doping process is followed by silicidation to form a silicide 213. In one or more embodiments, the silicide 213 is a metal silicide. In one or more embodiments, the silicide 213 is titanium silicide.

In some embodiments, the method 10 comprises, consists essentially of, or consists of operation 11, operation 12, operation 13, operation 14, operation 15, operation 16, operation 17, operation 18, operation 19, operation 20, operation 21, operation 22, operation 23, operation 24, operation 25, and operation 26. In some embodiments, the method 10 comprises, consists essentially of, or consists of operation 12, operation 13, operation 14, operation 15, operation 16, operation 17, operation 18, operation 19, operation 20, operation 21, operation 22, operation 23, operation 24, operation 25, and operation 26.

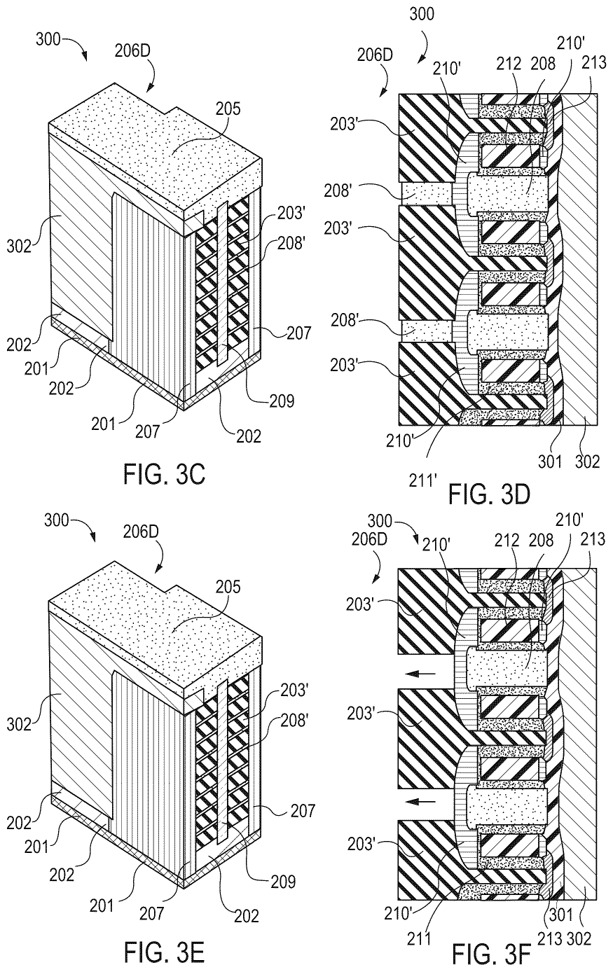

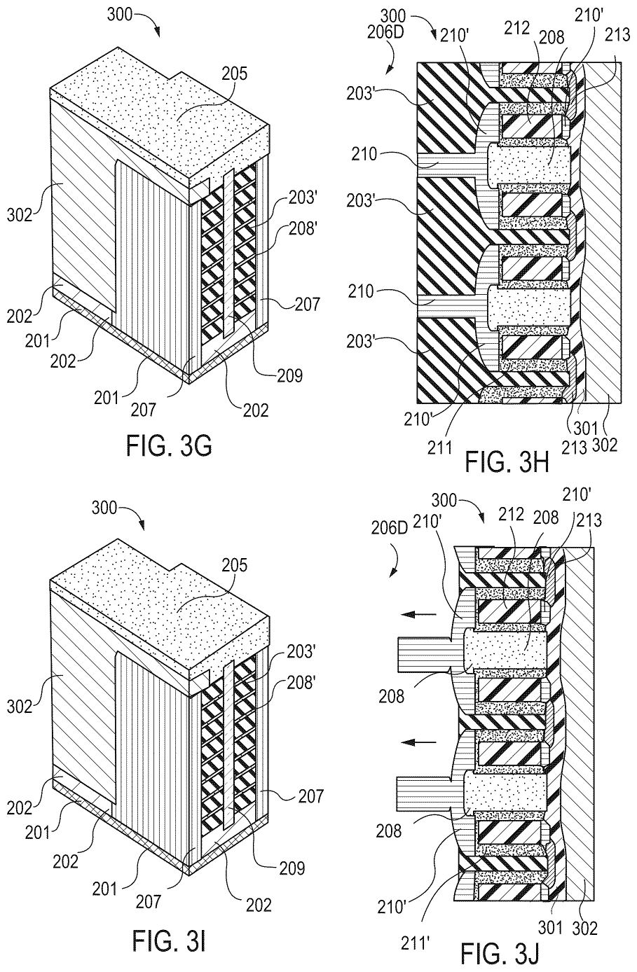

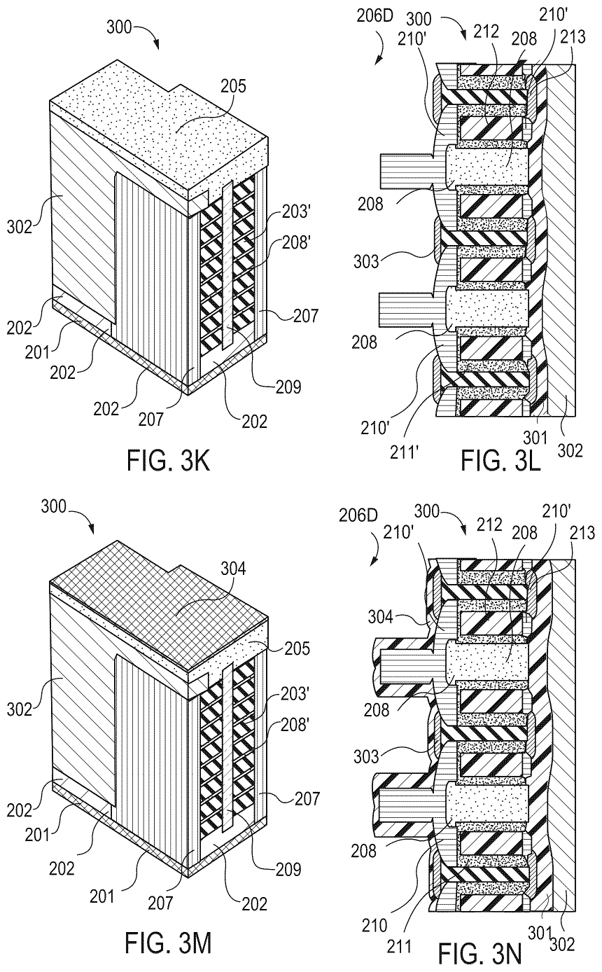

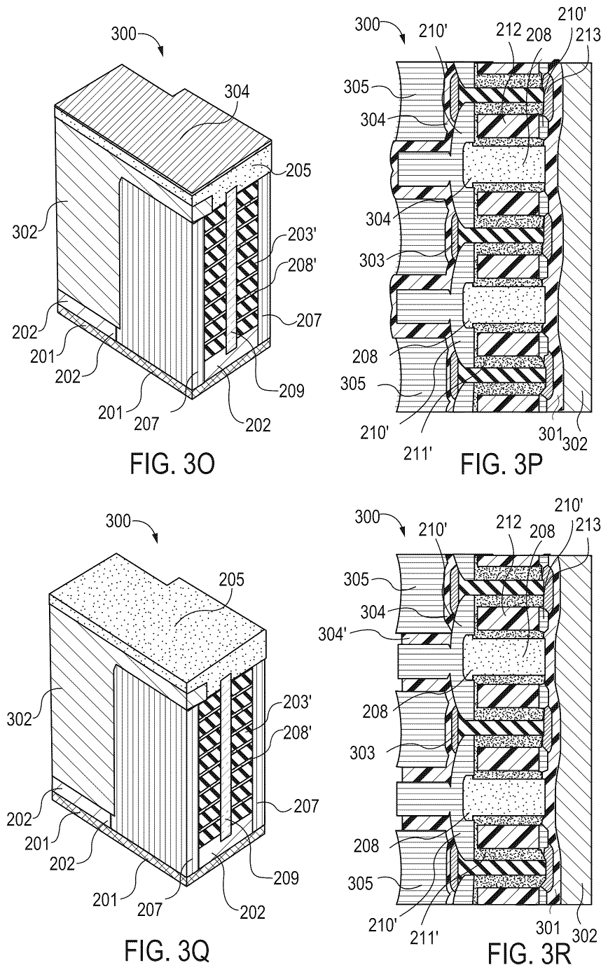

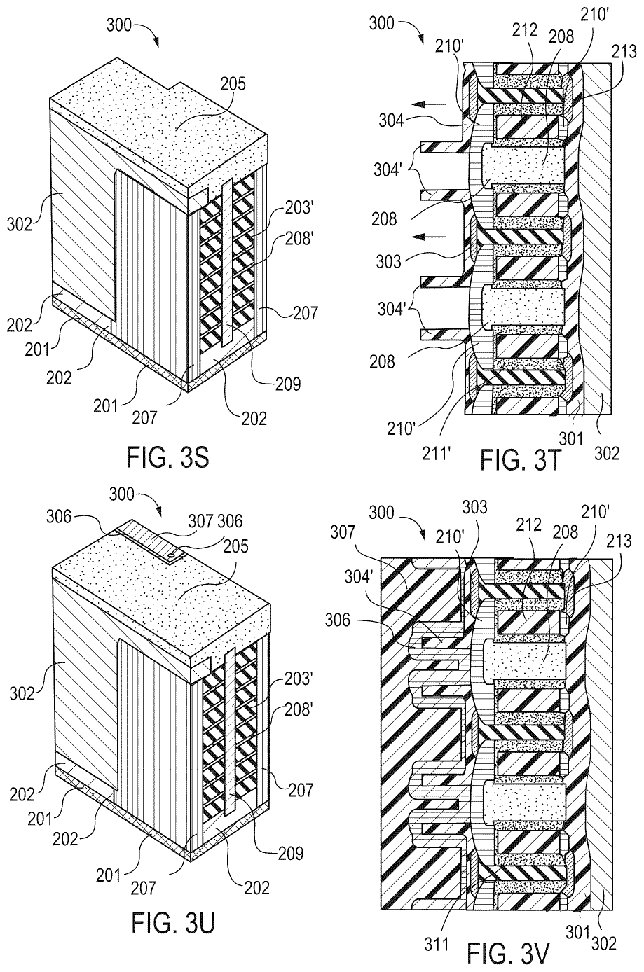

In one or more embodiments, once the method 10 is completed and the substrate 202 is processed up to the illustrated embodiment of FIG. 2Z, a semiconductor structure 300 is shown in FIGS. 3A-3V to illustrate processing the substrate 202 in accordance with the method 30.

The method 30 is described with reference to FIG. 1B and FIGS. 3A-3V. In one or more embodiments, the method 30 is a method of processing the substrate 202 of the semiconductor structure 300 as part of the integration scheme for manufacturing the memory device 100.

FIG. 3A illustrates a cross-sectional isometric view of the semiconductor structure 300 of FIG. 2Y after a bit line formation process, in accordance with operation 31. FIG. 3B illustrates an enlarged cross-sectional schematic view of the semiconductor structure 300 of FIG. 3A. In FIGS. 3A and 3B, in one or more embodiments, the bit line formation process includes depositing a bit line layer 301 in the third trench 206C. In one or more embodiments, the bit line layer 301 is a vertical layer in the third trench 206C that is deposited along the recessed dielectric layers 210′, the silicide 213, and the recessed gate oxide material 211′.

The bit line layer 301 can include any suitable material. In one or more embodiments, the bit line layer 301 comprises a metallic material. In one or more embodiments, the bit line layer 301 comprises titanium nitride (TiN).

The bit line layer 301 can have any suitable thickness. In one or more embodiments, the bit line layer 301 has a thickness in a range of from 10 nm to 30 nm.

In FIGS. 3A and 3B, in one or more embodiments, a dielectric material 302 is deposited directly on the bit line layer 301 to fill the third trench 206C. In one or more embodiments, the dielectric material 302 and the bit line layer 301 (along the recessed dielectric layers 210′, the silicide 213, and the recessed gate oxide material 211′) collectively fill the third trench 206C.

In one or more embodiments, the dielectric material 302 directly contacts one or more of the hard mask 205, the dielectric material 207, the recessed silicon layers 203′, or the substrate 202.

The dielectric material 302 can be any suitable dielectric material. In some embodiments, the dielectric material 302 comprises one or more of silicon oxide (SiOx), silicon nitride (SiN), or silicon oxynitride (SiON). In one or more embodiments, the dielectric material 302 comprises silicon oxide (SiOx).

FIG. 3C illustrates a cross-sectional isometric view of the semiconductor structure 300 of FIG. 3A after etching to form a fourth trench 206D, in accordance with operation 32. FIG. 3D illustrates an enlarged cross-sectional schematic view of the semiconductor structure 300 of FIG. 3C.

The fourth trench 206D defines a cavity through which a capacitor is formed. The fourth trench 206D can be formed by any suitable process, such as by one or more of the etching processes described herein. In one or more embodiments, a portion of the dielectric material 207 is removed to form the fourth trench 206D. In one or more embodiments, the fourth trench 206D is formed by top hard mask 205 opening and subsequent ashing of the sacrificial layer 209 (e.g., carbon). In FIG. 3D, once the fourth trench 206D is formed, a left side of the recessed dielectric layers 208′ and the recessed silicon layers 203′ is exposed.

FIG. 3E illustrates a cross-sectional isometric view of the semiconductor structure 300 of FIG. 3C after etching, in accordance with operation 33. FIG. 3F illustrates an enlarged cross-sectional schematic view of the semiconductor structure 300 of FIG. 3E. In FIGS. 3E and 3F, in on3 or more embodiments, the substrate 202 is etched to remove the recessed dielectric layers 208′ and etch a portion of the recessed silicon layers 203′ in the fourth trench 206D.

In one or more embodiments, etching the substrate 202 in accordance with the illustrated embodiments of FIGS. 3E and 3F comprises any suitable etching process, such as the etching processes described herein. In one or more embodiments, the recessed dielectric layers 208′ are removed entirely, and the recessed silicon layers 203′ are trimmed by an amount in a range of from 1 nm to 10 nm, by exposing the substrate 202 to tetramethylammonium hydroxide (TMAH). The complete removal of the recessed dielectric layers 208′ is denoted by the arrows pointing to the fourth trench 206D in FIG. 3F.

FIG. 3G illustrates a cross-sectional isometric view of the semiconductor structure 300 of FIG. 3E after depositing a sacrificial layer, i.e., the dielectric material 210, to fill the capacitor, in accordance with operation 34. FIG. 3H illustrates an enlarged cross-sectional schematic view of the semiconductor structure 300 of FIG. 3G. In FIGS. 3G and 3H, in one or more embodiments, the sacrificial layer, i.e., the dielectric material 210, is deposited in the openings formed between each of the recessed silicon layers 203′ (replacing the recessed dielectric layers 208′ that were present in FIG. 3D).

The dielectric material 210 deposited in the openings formed between each of the recessed silicon layers 203′ to fill the capacitor can be any suitable dielectric material. In one or more embodiments, the dielectric material 210 in FIGS. 3G and 3H comprises doped or undoped silicon nitride, doped or undoped silicon oxide, such as, for example, boron-doped silicon oxide, phosphorous-doped silicon oxide, boron/phosphorous-doped silicon oxide, or combinations thereof. In one or more embodiments, the dielectric material 210 in FIGS. 3G and 3H comprises silicon nitride (SiN).

FIG. 3I illustrates a cross-sectional isometric view of the semiconductor structure 300 of FIG. 3G after etching, in accordance with operation 35. FIG. 3J illustrates an enlarged cross-sectional schematic view of the semiconductor structure 300 of FIG. 3I. In FIGS. 3I and 3J, the substrate 202 is etched to remove the recessed silicon layers 203′ from the capacitor to expose a capacitor side contact of a transistor.

In one or more embodiments, etching the substrate 202 to remove the recessed silicon layers 203′ from the capacitor comprises any suitable etching process, such as the etching processes described herein. In one or more embodiments, the recessed silicon layers 203′ are removed by exposing the substrate 202 to tetramethylammonium hydroxide (TMAH). In FIGS. 3I and 3J, the recessed dielectric layers 210′ remain on the capacitor side contact of the transistor after removal of the recessed silicon layers 203′, and a surface of the recessed dielectric layers 210′ is exposed. In FIGS. 3I and 3J, in one or more embodiments, there is a portion of the recessed silicon layers 203′ remaining in the semiconductor structure 300 in contact with the recessed dielectric layers 210′ and the recessed gate oxide material 211′.

FIG. 3K illustrates a cross-sectional isometric view of the semiconductor structure 300 of FIG. 3I after a doping process, in accordance with operation 36. FIG. 3L illustrates an enlarged cross-sectional schematic view of the semiconductor structure 300 of FIG. 3J. In FIGS. 3K and 3L, in one or more embodiments, the doping process is an N+ doping process in which, on the capacitor side contact in the fourth trench 206D, the recessed dielectric layers 210′ that were exposed (in FIG. 3J) are doped with an n-type dopant. In one or more embodiments, the n-type dopant is phosphorous (P). In one or more embodiments, the recessed dielectric layers 210′ that were exposed (in FIG. 3J) are exposed to gas phase phosphine (PH₃) as a doping gas at temperature in a range of from 500 °C to 900 °C.

In one or more embodiments, the N+ doping process is followed by silicidation to form a silicide 303. In one or more embodiments, the silicide 303 is a metal silicide. In one or more embodiments, the silicide 303 is titanium silicide. In one or more embodiments, the silicide 303 is the same as the silicide 213.

In one or more embodiments, in FIG. 3L, the silicide 303 is formed directly on the recessed dielectric layers 210′. In one or more embodiments, in FIG. 3L, the silicide 303 is formed directly on the portion of the recessed silicon layers 203′ remaining in the semiconductor structure 300 in contact with the recessed dielectric layers 210′ and the recessed gate oxide material 211′.

FIG. 3M illustrates a cross-sectional isometric view of the semiconductor structure 300 of FIG. 3K after depositing a bottom electrode 304, in accordance with operation 37. FIG. 3N illustrates an enlarged cross-sectional schematic view of the semiconductor structure 300 of FIG. 3M. In FIGS. 3M and 3N, in one or more embodiments, the bottom electrode 304 is formed on top of the hard mask 205 and on top of the recessed dielectric layers 210′ and the silicide 303 on the capacitor side contact of the transistor.

The bottom electrode 304 can be deposited by any suitable deposition technique. The bottom electrode 304 can include any suitable material. In one or more embodiments, the bottom electrode 304 comprises a metallic material. In one or more embodiments, the bottom electrode 304 comprises titanium nitride (TiN).

FIG. 3O illustrates a cross-sectional isometric view of the semiconductor structure 300 of FIG. 3M after depositing a sacrificial layer, i.e., a dielectric material 305, to fill the capacitor side contact of the transistor, in accordance with operation 38. FIG. 3P illustrates an enlarged cross-sectional schematic view of the semiconductor structure 300 of FIG. 3O. In FIGS. 3O and 3P, in one or more embodiments, the sacrificial layer, i.e., the dielectric material 305, is deposited directly on the bottom electrode to fill openings within the fourth trench 206D.

The dielectric material 305 deposited in the openings within the fourth trench 206D to fill the capacitor side contact of the transistor can be any suitable dielectric material. In one or more embodiments, the dielectric material 305 in FIGS. 3O and 3P comprises doped or undoped silicon nitride, doped or undoped silicon oxide, such as, for example, boron-doped silicon oxide, phosphorous-doped silicon oxide, boron/phosphorous-doped silicon oxide, or combinations thereof. In one or more embodiments, the dielectric material 305 in FIGS. 3O and 3P comprises silicon nitride (SiN).

FIG. 3Q illustrates a cross-sectional isometric view of the semiconductor structure 300 of FIG. 3O after etching, in accordance with operation 49. FIG. 3R illustrates an enlarged cross-sectional schematic view of the semiconductor structure 300 of FIG. 3Q. In FIGS. 3Q and 3R, in one or more embodiments, a portion of the bottom electrode 304 is removed (to form etched bottom electrode 304′) to isolate the bottom electrode 304 per each cell.

In one or more embodiments, as will be described in greater detail herein, each cell is defined by one transistor comprised of the silicon channel having a source region/drain region, the gate oxide material 211, a top gate, e.g., gate 212 and a bottom gate, e.g., gate 212, and one cap comprised of the bottom electrode 304, the high-κ dielectric layer 306, and top electrode 307.

The portion of the bottom electrode 304 can be removed (to form the etched bottom electrode 304′) using any suitable etching process, such as one or more of the etching processes described herein.

FIG. 3S illustrates a cross-sectional isometric view of the semiconductor structure 300 of FIG. 3Q after etching, in accordance with operation 40. FIG. 3T illustrates an enlarged cross-sectional schematic view of the semiconductor structure 300 of FIG. 3S. In FIGS. 3S and 3T, in one or more embodiments, the sacrificial layer, i.e., the dielectric material 305, is removed to expose each of the etched bottom electrode 304, the bottom electrode 304, and the recessed dielectric layers 210′ on the capacitor side contact of the transistor.

In one or more embodiments, etching to remove the sacrificial layer, i.e., the dielectric material 305, can include any suitable etching process, such as one or more of the etching processes described herein. In one or more embodiments, etching to remove the sacrificial layer, i.e., the dielectric material 305, comprises exposing the substrate 202 to hot phosphoric acid (H₃PO₄).

FIG. 3U illustrates a cross-sectional isometric view of the semiconductor structure 300 of FIG. 3S after a deposition process, in accordance with operation 41. FIG. 3V illustrates an enlarged cross-sectional schematic view of the semiconductor structure 300 of FIG. 3U. In FIGS. 3U and 3V, in one or more embodiments, the deposition process comprises depositing a high-κ dielectric layer 306 directly on each of the etched bottom electrode 304′, the bottom electrode 304, and the recessed dielectric layers 210′ on the capacitor side contact of the transistor, and depositing a top electrode 307 directly on the high-κ dielectric layer 306 to fill the fourth trench 206D. In one or more embodiments, the top electrode 307 and the high-κ dielectric layer 306 on each of the etched bottom electrode 304′, the bottom electrode 304, and the recessed dielectric layers 210′ collectively fill the fourth trench 206D, i.e., the capacitor side contact of the transistor.

The high-κ dielectric layer 306 can be deposited using any suitable deposition technique and the high-κ dielectric layer 306 can have any suitable thickness. The high-κ dielectric layer 306 can include any high-κ dielectric material. In one or more embodiments, the high-κ dielectric layer 306 comprises hafnium oxide, zirconium oxide, hafnium zirconium oxide, or combinations thereof.

The top electrode 307 can be deposited using any suitable deposition technique and the top electrode 307 can have any suitable thickness. The top electrode 307 can include any suitable material. In one or more embodiments, the top electrode 307 comprises a metallic material. In one or more embodiments, the top electrode 307 comprises titanium nitride (TiN).

In some embodiments, the method 30 comprises, consists essentially of, or consists of operation 31, operation 32, operation 33, operation 34, operation 35, operation 36, operation 37, operation 38, operation 39, operation 40, and operation 41.

In one or more embodiments, once the method 30 is completed and the substrate 202 is processed up to the illustrated embodiment of FIG. 3V, a semiconductor structure 300 is shown in FIG. 4A-4Q to illustrate processing the substrate 202 in accordance with the method 50.

FIG. 4A illustrates a cross-sectional isometric view of the semiconductor structure 400 of FIG. 3U after etching to form a fifth trench 206E, in accordance with operation 51. In one or more embodiments, the fifth trench 206E is formed by top hard mask 205 opening and subsequent ashing of a portion of the sacrificial layer 209 (e.g., carbon).

FIG. 4B illustrates a cross-sectional isometric view of the semiconductor structure 400 of FIG. 4A after etching to remove the sacrificial layer 209, in accordance with operation 52. In FIG. 4B, etching to remove the sacrificial layer 209 can include any suitable etching process, such as one or more of the etching processes described herein. In one or more embodiments, etching to remove the sacrificial layer 209 comprises ashing in an oxygen ambient.

In one or more embodiments, etching to remove the sacrificial layer 209 is configured to increase a height of the fifth trench 206E. In one or more embodiments, once the sacrificial layer 209 has been removed, the fifth trench 206E extends through the hard mask 205 to the top surface of the substrate 202.

FIG. 4C illustrates an enlarged cross-sectional schematic view of the semiconductor structure 400 of FIG. 4B. In FIG. 4C, the semiconductor structure 400 having the array region AR, a transition region TR, and the word line pad region WLP is illustrated. Each of the array region AR, the transition region TR, and the word line pad region WLP are separated by dashed lines shown in phantom.

FIG. 4D illustrates a cross-sectional isometric view of the semiconductor structure 400 of FIG. 4B after etching, in accordance with operation 53. FIG. 4E illustrates an enlarged cross-sectional schematic view of the semiconductor structure 400 of FIG. 4D. In FIGS. 4D and 4E, in one or more embodiments, the dielectric layers 208 are removed from the word line pad region WLP, and the silicon layers 203 in the word line pad region WLP are trimmed to form the recessed silicon layers 203′.

In one or more embodiments, etching the substrate 202 in accordance with the illustrated embodiments of FIGS. 4D and 4E comprises any suitable etching process, such as the etching processes described herein. In one or more embodiments, the dielectric layers 208 are removed entirely, and the recessed silicon layers 203′ are trimmed by an amount in a range of from 1 nm to 10 nm, by exposing the substrate 202 to tetramethylammonium hydroxide (TMAH). The complete removal of the dielectric layers 208 is denoted by the arrows pointing to a right side of the word line pad region WLP in FIG. 4E.

FIG. 4F illustrates a cross-sectional isometric view of the semiconductor structure of FIG. 4D after laterally filling a portion of the semiconductor structure 400 with the dielectric material 210, in accordance with operation 54. FIG. 4G illustrates an enlarged cross-sectional schematic view of the semiconductor structure 400 of FIG. 4F.

In one or more embodiments, the dielectric material 210 is formed in the space between each of the recessed silicon layers 203′. In one or more embodiments, the dielectric material 210 replaces the dielectric material 208, which was removed in FIGS. 4D and 4E.

The dielectric material 210 can be deposited by any suitable deposition technique and can have any suitable thickness. The dielectric material 210 can be any suitable dielectric material. In one or more embodiments, the dielectric material 210 deposited in FIGS. 4F and 4G comprises silicon nitride (SiN), silicon oxide (SiOx), silicon oxynitride (SiON), or combinations thereof. In one or more embodiments, the dielectric material 210 deposited in FIGS. 4F and 4G comprises silicon nitride. In one or more embodiments, the dielectric material 210 deposited in FIGS. 4F and 4G is a word line insulator layer.

FIG. 4H illustrates a cross-sectional isometric view of the semiconductor structure 400 of FIG. 4F after etching, in accordance with operation 55. FIG. 4I illustrates an enlarged cross-sectional schematic view of the semiconductor structure 400 of FIG. 4H. In FIGS. 4H and 4I, in one or more embodiments, the substrate 202 is etched to remove the recessed silicon layers 203′ from the capacitor side of the transistor

In one or more embodiments, in FIGS. 4H and 4I, etching the substrate 202 to remove the recessed silicon layers 203′ from the capacitor comprises any suitable etching process, such as the etching processes described herein. In one or more embodiments, the recessed silicon layers 203′ are removed by exposing the substrate 202 to tetramethylammonium hydroxide (TMAH). In FIGS. 4H and 4I, the recessed dielectric layers 210′ remain on the capacitor side contact of the transistor after removal of the recessed silicon layers 203′, and a surface of the recessed dielectric layers 210′ is exposed. In FIGS. 4H and 4I, in one or more embodiments, the recessed silicon layers 203′ are removed entirely from the word line pad region WLP.

In FIGS. 4H and 4I, in one or more embodiments, there is a portion of the recessed silicon layers 203′ remaining in the semiconductor structure 400 in contact with the recessed gate oxide material 211′ in the transition region TR.

FIG. 4J illustrates a cross-sectional isometric view of the semiconductor structure 400 of FIG. 4H after etching, in accordance with operation 56. FIG. 4K illustrates an enlarged cross-sectional schematic view of the semiconductor structure 400 of FIG. 4J. In FIGS. 4J and 4K, in one or more embodiments, the substrate 202 is etched to remove a portion of the recessed gate oxide material 211′ in the transition region TR, and to remove a portion of the recessed dielectric layers 210′ in the word line pad region WLP. In one or more embodiments where the substrate 202 is etched to remove the portion of the recessed gate oxide material 211′ in the transition region TR, the recessed silicon layers 203′ in the transition region TR are exposed in a direction parallel to the substrate 202.

In FIGS. 4J and 4K, the substrate 202 can be etched by any suitable etching process, such as one or more of the etching processes described herein. After etching to remove the silicon layers 203 in the word line pad region (WLP), a plurality of word line cavities (each word line cavity is represented by “WLC”) is formed. Each word line cavity WLC is defined by the space between the recessed dielectric layers 210′ in the word line pad region WLP, and extends into the transition region TR to the exposed surface of the recessed silicon layers 203′ (i.e., parallel in a z-direction relative to the substrate 202).

FIG. 4L illustrates a cross-sectional isometric view of the semiconductor structure of FIG. 4J after filling a portion of the semiconductor structure 400 with a metallic material, in accordance with operation 57. FIG. 4M illustrates an enlarged cross-sectional schematic view of the semiconductor structure 400 of FIG. 4L. In FIGS. 4L and 4M, in one or more embodiments, the metallic material filling the portion of the semiconductor structure 400 is a word line layer 402. In one or more embodiments, the word line layer 402 fills the word line cavity WLC. In one or more embodiments where the word line layer 402 fills the word line cavity WLC, the word line layer 402 is in contact with the recessed silicon layers 203′ in the transition region TR. In one or more embodiments where the word line layer 402 fills the word line cavity WLC, the word line layer 402 is in contact with the recessed gate oxide material 211′ in the transition region TR.

The word line layer 402 can be any suitable metallic material. In one or more embodiments, the word line layer 402 comprises molybdenum (Mo), tungsten (W), titanium nitride (TiN), or n-doped silicon (N⁺Si).

FIG. 4N illustrates a cross-sectional isometric view of the semiconductor structure of FIG. 4L after filling a portion of the semiconductor structure 400 with a dielectric material 403, in accordance with operation 58. In FIG. 4N, in one or more embodiments, the fifth trench 206E is filled with the dielectric material 403. The dielectric material 403 can be deposited by any suitable deposition technique, and the dielectric material 403 can have any suitable thickness.

The dielectric material 403 can be any suitable dielectric material. In some embodiments, the dielectric material 403 comprises one or more of silicon oxide (SiOx), silicon nitride (SiN), or silicon oxynitride (SiON). In one or more embodiments, the dielectric material 403 comprises silicon oxide (SiOx).

FIG. 4O illustrates a cross-sectional isometric view of the semiconductor structure 400 of FIG. 4N after etching, in accordance with operation 59. FIG. 4P illustrates an enlarged cross-sectional schematic view of the semiconductor structure 400 of FIG. 4O. In FIGS. 4O and 4P, in one or more embodiments, the substrate 202 is etched to form a plurality of word line cavities 404. In the illustrated embodiment of FIG. 4O, the plurality of word line cavities 404 extend through the hard mask 205 down to the top surface of the substrate 202. In one or more embodiments, the plurality of word line cavities 404 extend vertically relative to the substrate 202.

In the illustrated embodiment of FIG. 4P, the plurality of word line cavities 404 extend through the word line pad region WLP. In one or more embodiments, the plurality of word line cavities 404 extend through the recessed dielectric layers 210′ and the word line layer 402 in the word line pad region WLP. In the illustrated embodiment of FIG. 4P, one or more of the plurality of word line cavities 404 may have a different depth than another of the cavities. The skilled artisan will appreciate that although two cavities are shown in FIG. 4P, the plurality of word line cavities 404 can include any number of cavities. The plurality of word line cavities 404 can define any suitable shape. In one or more embodiments, the plurality of word line cavities define a trench having a bottom surface and sidewall surfaces.

FIG. 4Q illustrates a cross-sectional isometric view of the semiconductor structure 400 of FIG. 4O after a deposition process, in accordance with operation 60. FIG. 4R illustrates an enlarged cross-sectional schematic view of a portion of a memory device 100. In FIGS. 4Q and 4R, in one or more embodiments, the deposition process comprises a process to fill the plurality of word line cavities 404.

In one or more embodiments, the deposition process begins by depositing a liner layer 408 in each of the plurality of word line cavities 404. In one or more embodiments, the liner layer 408 is formed along the sidewall surfaces of the plurality of word line cavities 404. In one or more embodiments, the liner layer 408 is formed directly on the sidewall surfaces of the plurality of word line cavities 404.

The liner layer 408 can be deposited by any suitable deposition technique and the liner layer 408 can have any suitable thickness. The liner layer 408 can include any suitable dielectric material. In some embodiments, the liner layer 408 comprises one or more of silicon oxide (SiOx), silicon nitride (SiN), or silicon oxynitride (SiON). In some embodiments, the liner layer 408 comprises silicon oxide (SiOx).

In one or more embodiments, after depositing the liner layer 408 in each of the plurality of word line cavities 404, a barrier layer 409 is deposited directly on the liner layer 408.

In one or more embodiments, the barrier layer 409 is formed along the liner layer 408 on the sidewall surfaces and on the bottom surface of the plurality of word line cavities 404. In one or more embodiments, the barrier layer 409 is formed directly on the liner layer 408 on the sidewall surfaces and directly on the bottom surface of the plurality of word line cavities 404.

The barrier layer 409 can be deposited by any suitable deposition technique and the barrier layer 409 can have any suitable thickness. In one or more embodiments, the barrier layer 409 is conformally deposited by atomic layer deposition (ALD) directly on the liner layer 408 on the sidewall surfaces and directly on the bottom surface of the plurality of word line cavities 404. The barrier layer 409 can comprise any suitable material. In one or more embodiments, the barrier layer 409 comprises a metal nitride. In one or more embodiments, the barrier layer 409 comprises titanium nitride (TiN). In one or more embodiments, the barrier layer 409 comprises tantalum nitride (TaN).

In one or more embodiments, after depositing the barrier layer 409 in each of the plurality of word line cavities 404, a conductive layer 410 is deposited to fill each of the plurality of word line cavities 404. In one or more embodiments, the conductive layer 410 is deposited directly on the barrier layer 409.

The conductive layer 410 can be deposited by any suitable deposition technique and the conductive layer 410 can have any suitable thickness. The conductive layer 410 can comprise any suitable metallic material. In one or more embodiments, the conductive layer 410 comprises one or more of doped silicon, molybdenum (Mo), tungsten (W), titanium nitride (TiN), or tantalum nitride (TaN). In one or more embodiments, the conductive layer 410 comprises tungsten (W). In one or more embodiments, the conductive layer 410 comprises an alloy of tungsten (W) and titanium nitride (TiN).

In one or more embodiments, after depositing the conductive layer 410 to fill the plurality of word line cavities 404, a plurality of word line contacts are formed. In one or more embodiments, once the plurality of word line contacts are formed, fabrication of the portion of the memory device 100 shown in FIG. 4R is complete.

In some embodiments, the method 50 comprises, consists essentially of, or consists of operation 51, operation 52, operation 53, operation 54, operation 55, operation 56, operation 57, operation 58, operation 59, and operation 60. In some embodiments, the method 50 comprises, consists essentially of, or consists of operation 55, operation 56, and operation 60.

In one or more embodiments, the method 10, the method 30, and the method 50 collectively provide an integration scheme for manufacturing a memory device 100, shown in FIG. 4R-4U. In one or more embodiments, the substrate 202 is provided with the method 10 and the method 30 already completed, with the method 50 comprising, consisting essentially of, or consisting of operation 56, operation 57, operation 58, operation 59, and operation 60, or the method 50 comprising, consisting essentially of, or consisting of operation 55, operation 56, and operation 60.

The memory device 100 can include any memory device. In one or more embodiments, the memory device 100 is a NAND device. In one or more embodiments, the memory device 100 is a 3D-NAND device. In one or more embodiments, the memory device 100 is a 3D-DRAM device. In one or more embodiments, the memory device 100 is manufactured in accordance with the method 10, the method 30, and the method 50.

In the illustrated embodiments of 100, shown in FIG. 4R-4U, the memory device 100 includes the gate 212, which is representative of a plurality of word lines of the array region AR and the word line layer 402, which is representative of a plurality of word lines of the word line pad region WLP. In FIG. 4S, each of the plurality of word lines of the array region AR is connected to each of the plurality of word lines of the word line pad region WLP. As will be described further herein with respect to FIG. 4U, in some embodiments, of the plurality of word lines of the array region AR is connected to each of the plurality of word lines of the word line pad region WLP in a first direction and a second direction.

In each of FIGS. 4S, 4T, and 4U, “AR-WLP” represents connection of the array region AR and the word lined pad region WLP.

FIG. 4S illustrates a top schematic view of a portion of the memory device 100 of FIG. 4R. In particular, FIG. 4S illustrates the connection of the array region AR with the word line pad region WLP (i.e., AR-WLP).

In one or more embodiments, FIG. 4S illustrates a generic capacitor, such as the capacitor as described herein on top of a generic cell transistor, such as the transistors described herein. In one or more embodiments, FIG. 4S illustrates the bit liner layer 301 and a schematic representation of a source region/drain region (S/D) in the cell transistor. In FIG. 4S, the gate 212 is representative of a plurality of word lines of the array region AR and the word line layer 402 is representative of a plurality of word lines of the word line pad region WLP. In FIG. 4S, each of the plurality of word lines of the array region AR is connected to each of the plurality of word lines of the word line pad region WLP, represented by AR-WLP.

FIG. 4T illustrates a cross-sectional schematic view of a portion of the memory device 100 of FIG. 4S taken along line A-A′ and line Z-Z′. In particular, FIG. 4T illustrates the connection of the array region AR with the word line pad region WLP (i.e., AR-WLP) taken along line A-A′ and line Z-Z′. FIG. 4T illustrates a portion of the memory device 100 conveyed in FIG. 4S, where after depositing the conductive layer 410 to fill the plurality of word line cavities 404, the plurality of word line contacts are formed.

FIG. 4U illustrates an enlarged cross-sectional schematic view of a portion of the memory device 100. In particular, FIG. 4U illustrates the connection of the array region AR with the word line pad region WLP (i.e., AR-WLP) in a first direction D1 and a second direction D2. In one or more embodiments, the first direction D1 extends parallel in a z-direction relative to the substrate 202. In one or more embodiments, the second direction D2 extends vertically relative to the substrate 202.

The methods described herein can be performed in any suitable processing system. In one or more embodiments, each of the operations of the methods described herein are performed in situ in an integrated processing system. In one or more embodiments, one or more of the operations of the methods described herein are performed ex situ. The particular arrangement of processing chambers and components can be varied depending on the processing system and should not be taken as limiting the scope of the disclosure.

One or more embodiments are directed to a processing system comprising a central transfer station comprising at least one robot configured to move a wafer; a plurality of processing stations, each processing station connected to the central transfer station and providing a processing region separated from processing regions of adjacent processing stations; and a controller connected to the central transfer station and the plurality of processing stations. The controller is configured to activate the robot to move the wafer between processing stations, including selectively removing a plurality of first material layers from a film stack in an array region on the wafer. The array region includes at least two unit cells stacked vertically on the wafer. Each of the at least two unit cells includes a capacitor connected to a transistor. The transistor comprises a silicon channel and the film stack. The film stack comprises alternating layers of the plurality of first material layers, a plurality of second material layers, and a gate oxide material on the silicon channel. The controller is configured to active the robot to remove a portion of the gate oxide material to form a plurality of word line cavities between each of the plurality of second material layers; and deposit a conductive material in each of the plurality of word line cavities to form a plurality of word line contacts. The plurality of word line contacts are configured to connect the array region with a word line pad region of the memory device in a first direction and a second direction. In one or more embodiments, the processing system is configured to perform any and/or all of the methods described herein. In one or more embodiments, the processing system is configured to manufacture the memory device 100.

One or more embodiments are directed to a non-transitory computer readable medium including instructions, that, when executed by a controller of a processing system, causes the processing system to perform the operations of any of the methods described herein.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing a memory device, the method comprising:
selectively removing a plurality of first material layers from a film stack in an array region on a substrate, the array region including at least two unit cells stacked vertically on the substrate, each of the at least two unit cells including a capacitor connected to a transistor, the transistor comprising a silicon channel and the film stack, the film stack comprising alternating layers of the plurality of first material layers, a plurality of second material layers, and a gate oxide material on the silicon channel;
removing a portion of the gate oxide material to form a plurality of word line cavities between each of the plurality of second material layers; and
depositing a conductive material in each of the plurality of word line cavities to form a plurality of word line contacts,
wherein the plurality of word line contacts are configured to connect the array region with a word line pad region of the memory device in a first direction and a second direction.

2. The method of claim 1, wherein the plurality of first material layers comprises silicon (Si).

3. The method of claim 1, wherein the plurality of second material layers comprises silicon germanium (SiGe) or silicon oxide (SiOx).

4. The method of claim 1, wherein the gate oxide material comprises silicon oxide (SiOx).

5. The method of claim 1, wherein the conductive material comprises one or more of doped silicon, molybdenum (Mo), tungsten (W), titanium nitride (TiN), or tantalum nitride (TaN).

6. The method of claim 1, wherein the array region comprises a plurality of word lines and the word line pad region comprises a plurality of word lines.

7. The method of claim 6, wherein the plurality of word line contacts are configured to connect each of the plurality of word lines of the array region with each of the plurality of word lines of the word line pad region in the first direction and the second direction.

8. The method of claim 7, wherein the first direction extends parallel in a z-direction relative to the substrate.

9. The method of claim 7, wherein the second direction extends vertically relative to the substrate.

10. The method of claim 1, performed in situ in an integrated processing system.

11. The method of claim 1, wherein the memory device is a 3-D DRAM device.

12. A processing system comprising:
a central transfer station comprising at least one robot configured to move a wafer;
a plurality of processing stations, each processing station connected to the central transfer station and providing a processing region separated from processing regions of adjacent processing stations; and
a controller connected to the central transfer station and the plurality of processing stations, the controller configured to activate the robot to move the wafer between processing stations, including:
selectively removing a plurality of first material layers from a film stack in an array region on the wafer, the array region including at least two unit cells stacked vertically on the wafer, each of the at least two unit cells including a capacitor connected to a transistor, the transistor comprising a silicon channel and the film stack, the film stack comprising alternating layers of the plurality of first material layers, a plurality of second material layers, and a gate oxide material surrounding the silicon channel;
removing a portion of the gate oxide material to form a plurality of word line cavities between each of the plurality of second material layers; and
depositing a conductive material in each of the plurality of word line cavities to form a plurality of word line contacts, wherein the plurality of word line contacts are configured to connect the array region with a word line pad region of the memory device in a first direction and a second direction.

13. A memory device comprising:
an array region including at least two unit cells stacked vertically on a substrate, the array region including a plurality of word lines; and
a word line pad region including a plurality of word lines, wherein each of the plurality of word lines of the array region is connected to each of the plurality of word lines of the word line pad region in a first direction and a second direction.

14. The memory device of claim 13, wherein each of the plurality of word lines of the array region independently comprise one or more of doped silicon, molybdenum (Mo), tungsten (W), titanium nitride (TiN), or tantalum nitride (TaN).

15. The memory device of claim 13, wherein each of the plurality of word lines of the word line pad region independently comprise one or more of doped silicon, molybdenum (Mo), tungsten (W), titanium nitride (TiN), or tantalum nitride (TaN).

16. The memory device of claim 13, wherein each of the plurality word lines of the array region and each of the plurality of word lines of the word line pad region independently comprise one or more of doped silicon, molybdenum (Mo), tungsten (W), titanium nitride (TiN), or tantalum nitride (TaN).

17. The memory device of claim 16, wherein each of the plurality word lines of the array region comprise a different material than each of the plurality of word lines of the word line pad region.

18. The memory device of claim 13, wherein the first direction extends parallel in a z-direction relative to the substrate.

19. The memory device of claim 13, wherein the second direction extends vertically relative to the substrate.

20. The memory device of claim 13, comprising a 3-D DRAM device.
